(19) United States
(12) Patent Application Publication
(10) Pub. No.: US 2025/0248084 A1
(43) Pub. Date: Jul. 31, 2025

(54) SEMICONDUCTOR DEVICE AND METHOD OF FABRICATING THE SAME

(71) Applicant: Samsung Electronics Co., Ltd., Suwon-si (KR)

(72) Inventors: Inhyun SONG, Suwon-si (KR); Jongsu KIM, Suwon-si (KR); Myung Gil KANG, Suwon-si (KR); Ohseong KWON, Suwon-si (KR); Junggil YANG, Suwon-si (KR); Inho YEO, Suwon-si (KR); Eunguk CHUNG, Suwon-si (KR)

(73) Assignee: Samsung Electronics Co., Ltd., Suwon-si (KR)

(21) Appl. No.: 18/761,826

(22) Filed: Jul. 2, 2024

(30) Foreign Application Priority Data
Jan. 29, 2024 (KR) 10-2024-0013464

(51) Int. Cl. H01L 29/06; H01L 27/092; H01L 29/423; H01L 29/66; H01L 29/775; H10B 10/00

(52) U.S. Cl. CPC H10D 62/121; H10B 10/125; H10D 30/014; H10D 30/43; H10D 30/6735; H10D 84/85

(57) ABSTRACT

A semiconductor device may include an active pattern on an active region of a substrate, a channel pattern on the active pattern and including first, second, and third semiconductor patterns that are stacked to be spaced apart from each other, a gate electrode on the channel pattern, and a gate dielectric layer between the channel pattern and the gate electrode. The gate dielectric layer may include an interface layer, and first, second, and third high-k dielectric layers that are sequentially stacked on the interface layer. The first high-k dielectric layer may include a first dipole element, and the second high-k dielectric layer may include a second dipole element.

### CROSS-REFERENCE TO RELATED APPLICATION

This U.S. nonprovisional application claims priority under 35 U.S.C § 119 to Korean Patent Application No. 10-2024-0013464 filed on Jan. 29, 2024 in the Korean Intellectual Property Office, the disclosure of which is hereby incorporated by reference in its entirety.

### BACKGROUND

The present inventive concepts relate to semiconductor devices, and more particularly, to semiconductor devices including a field effect transistor.

A semiconductor device includes an integrated circuit consisting of metal oxide semiconductor field effect transistors (MOSFETs). As size and design rule of the semiconductor device are gradually decreased, sizes of the MOSFETs are also continuously scaled down. The scale down of MOSFETs may deteriorate operating characteristics of the semiconductor device. Accordingly, research has been variously conducted to manufacture the semiconductor device having excellent performances while overcoming limitations due to integration of the semiconductor device.

### SUMMARY

Some example embodiments of the present inventive concepts provide semiconductor devices having increased reliability and improved electrical characteristics.

Some example embodiments of the present inventive concepts provide methods of fabricating a semiconductor device having increased reliability and improved electrical characteristics.

The object of the present inventive concepts is not limited to the mentioned above, and other objects which have not been mentioned above will be clearly understood to those skilled in the art from the following description.

According to an example embodiment of the present inventive concepts, a semiconductor device includes an active pattern on an active region of a substrate, a channel pattern on the active pattern, the channel pattern including first, second, and third semiconductor patterns that are stacked to be spaced apart from each other, a gate electrode on the channel pattern, and a gate dielectric layer between the channel pattern and the gate electrode, wherein the gate dielectric layer includes an interface layer, and first, second, and third high-k dielectric layers that are sequentially stacked on the interface layer, and the first high-k dielectric layer includes a first dipole element. The second high-k dielectric layer may include a second dipole element.

According to an example embodiment of the present inventive concepts, a semiconductor device includes a substrate including a first active region and a second active region that are adjacent to each other, a first active pattern on the first active region and a second active pattern on the second active region, a first channel pattern on the first active pattern and a second channel pattern on the second active pattern, a first gate electrode on the first channel pattern and a second gate electrode on the second channel pattern, a first gate dielectric layer between the first channel pattern and the first gate electrode, and a second gate dielectric layer between the second channel pattern and the second gate electrode. Each of the first and second gate dielectric layers may include a first high-k dielectric layer and a second high-k dielectric layer. The first high-k dielectric layer of the first gate dielectric layer may include a first dipole element. The first high-k dielectric layer of the second gate dielectric layer may include a second dipole element.

According to some embodiments of the present inventive concepts, a semiconductor device may comprise: a substrate including a first region and a second region that are spaced apart from each other, a logic cell on the first region and including a logic transistor, and a memory cell on the second region and including a memory transistor. The logic transistor may include: a first channel pattern, a first gate electrode on the first channel pattern, and a first gate dielectric layer between the first channel pattern and the first gate electrode. The memory transistor may include: a second channel pattern, a second gate electrode on the second channel pattern, and a second gate dielectric layer between the second channel pattern and the second gate electrode. Each of the first and second gate dielectric layers may include a first high-k dielectric layer and a second high-k dielectric layer. The first gate dielectric layer may further include a first dipole layer between the first high-k dielectric layer and the second high-k dielectric layer.

### BRIEF DESCRIPTION OF DRAWINGS

FIGS. 1 to 3 illustrate conceptual diagrams showing logic cells of a semiconductor device according to some example embodiments of the present inventive concepts.

FIG. 4 illustrates a plan view showing a semiconductor device according to an example embodiment of the present inventive concepts.

FIGS. 5A, 5B, 5C, and 5D illustrate cross-sectional views respectively taken along lines A-A′, B-B′, C-C′, and D-D′ of FIG. 4.

FIG. 6A illustrates an enlarged view of section X of FIG. 5D.

FIGS. 6B and 6C illustrate enlarged views showing sections P1 and P2 of FIG. 6A, respectively.

FIGS. 7A, 7B, and 7C illustrate plan views showing a semiconductor device according to some example embodiments of the present inventive concepts.

FIGS. 8A, 8B, and 8C illustrate cross-sectional views respectively taken along line E-E′ of FIG. 7B, line F-F′ of FIG. 7B, and line G-G′ of FIG. 7C.

FIGS. 9A and 9B illustrate enlarged views showing sections X1 and Y1 of FIG. 8A, respectively.

FIGS. 9C and 9D illustrate enlarged views showing sections X2 and Y2 of FIG. 8B, respectively.

FIGS. 9E and 9F illustrate enlarged views showing sections X3 and Y3 of FIG. 8C, respectively.

FIGS. 10A and 10B illustrate enlarged views showing sections X1 and Y1 of FIG. 8A, respectively.

FIG. 10C illustrates an enlarged view showing section P1 of FIG. 10A.

FIGS. 11A to 14B illustrate diagrams showing a method of fabricating a semiconductor device according to an example embodiment of the present inventive concepts.

### DETAILED DESCRIPTION

The following will now describe some example embodiments of the present inventive concepts with reference to the accompanying drawings. Like reference numerals may indicate like components throughout the description.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

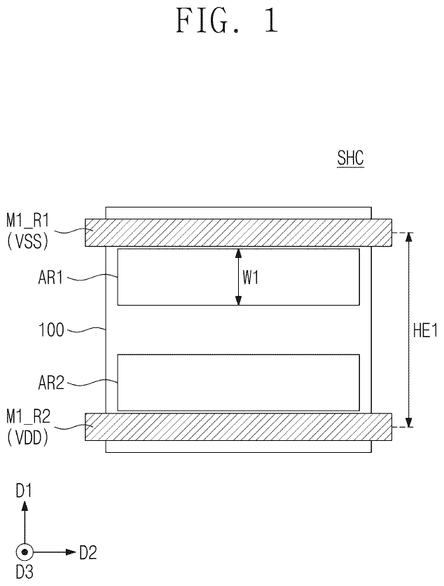

FIGS. 1 to 3 illustrate conceptual diagrams showing logic cells of a semiconductor device according to some example embodiments of the present inventive concepts.

Referring to FIG. 1, a single height cell SHC may be provided. For example, a substrate 100 may be provided thereon with a first power line M1_R1 and a second power line M1_R2. For example, the first power line M1_R1 may be a ground line VSS, and the second power line M1_R2 may be a power line VDD.

The single height cell SHC may be defined between the first power line M1_R1 and the second power line M1_R2. The single height cell SHC may include one first active region AR1 and one second active region AR2. One of the first and second active regions AR1 and AR2 may be a PMOSFET region, and the other of the first and second active regions AR1 and AR2 may be an NMOSFET region. The single height cell SHC may have a complementary metal oxide semiconductor (CMOS) structure provided between the first power line M1_R1 and the second power line M1_R2.

Each of the first and second active regions AR1 and AR2 may have a first width W1 in a first direction D1. The single height cell SHC may have a first height HE1 in the first direction D1. The first height HE1 may be substantially the same as a distance (e.g., pitch) between the first power line M1_R1 and the second power line M1_R2.

The single height cell SHC may constitute one logic cell. In this description, the logic cell may mean a logic device, such as AND, OR, XOR, XNOR, and inverter, that performs a specific function. For example, the logic cell may include transistors for constituting a logic device and wiring lines that connect the transistors to each other.

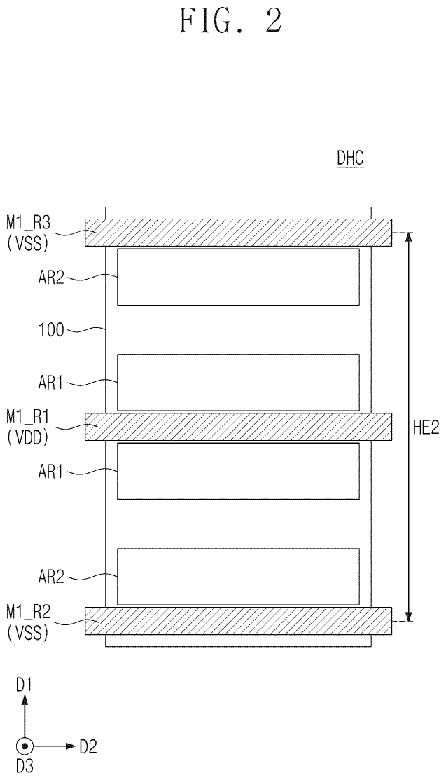

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. For example, the second and third power lines M1_R2 and M1_R3 may be a ground line VSS, and the first power line M1_R1 may be a power line VDD.

The double height cell DHC may be defined between the second power line M1_R2 and the third power line M1_R3. The double height cell DHC may include two first active regions AR1 and two second active regions AR2.

One of the two second active regions AR2 may be adjacent to the second power line M1_R2. The other of the two second active regions AR2 may be adjacent to the third power line M1_R3. The two first active regions AR1 may be adjacent to the first power line M1_R1. When viewed in plan, the first power line M1_R1 may be disposed between the two first active regions AR1.

The double height cell DHC may have a second height HE2 in a first direction D1. The second height HE2 may be about twice the first height HE1 of FIG. 1. The two first active regions AR1 of the double height cell DHC may be collectively connected to act as one active region.

In this description, the double height cell DHC may be defined as a multi-height cell. For example, the multi-height cell may include a triple height cell whose cell height is about three times that of the single height cell SHC.

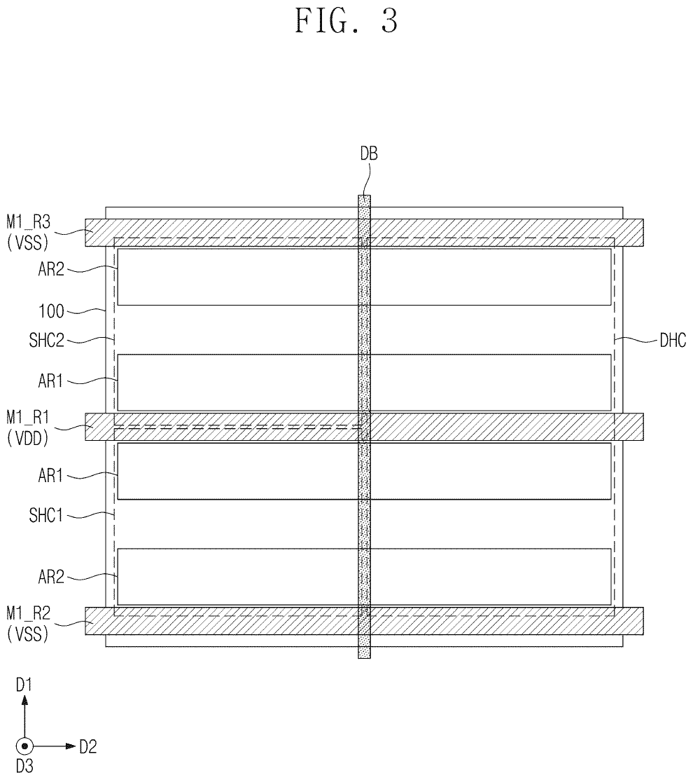

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

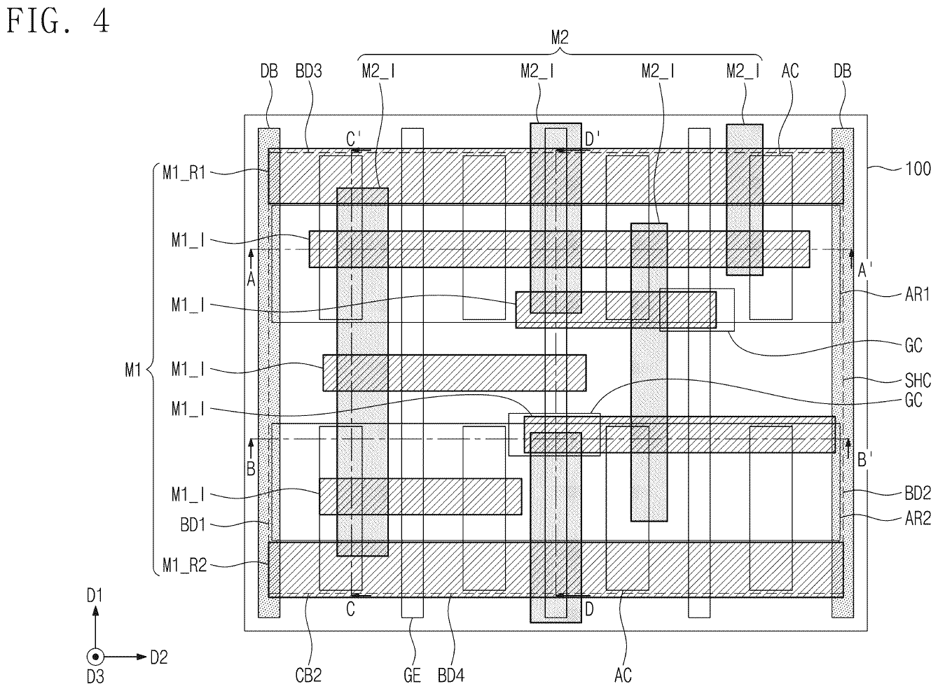

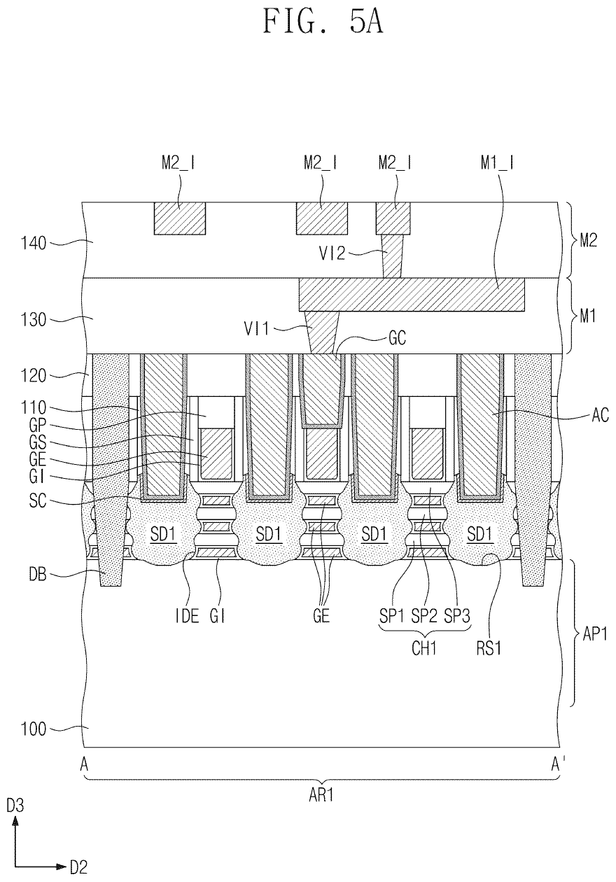

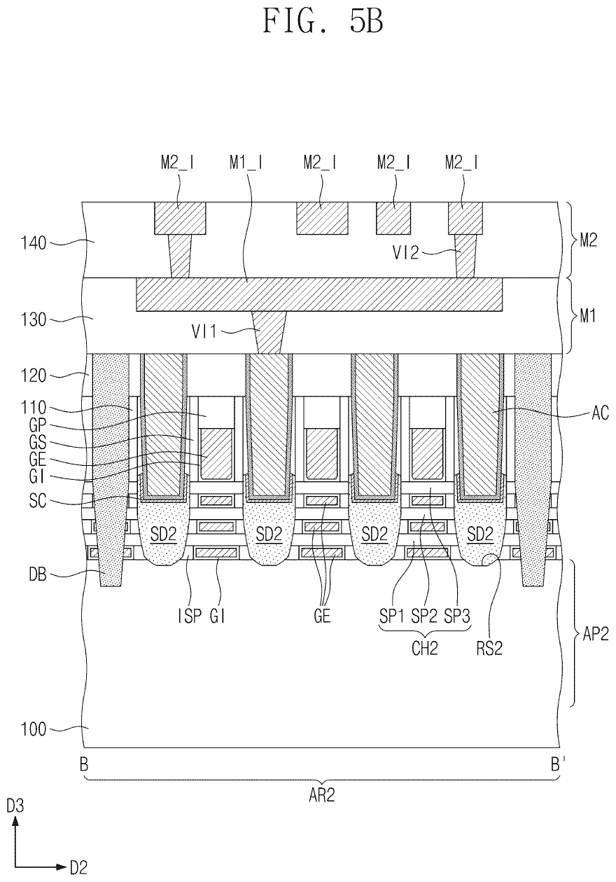

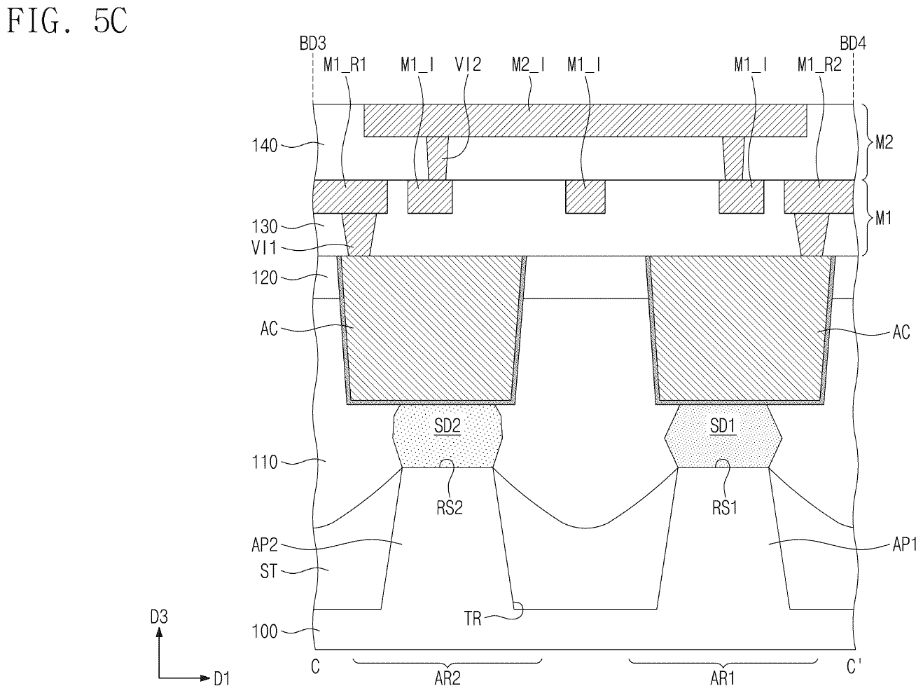

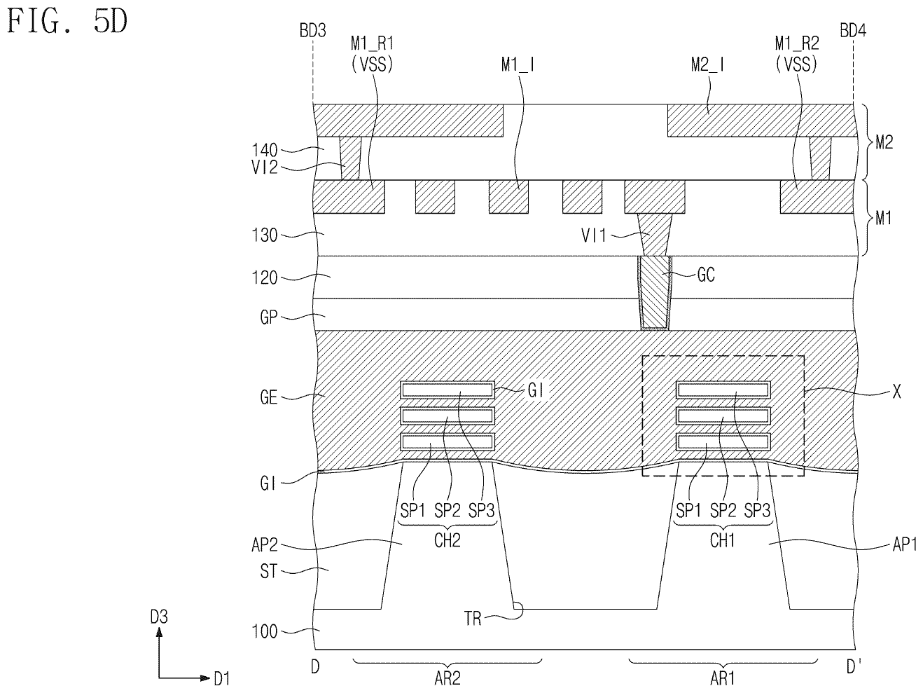

FIG. 4 illustrates a plan view showing a semiconductor device according to an example embodiment of the present inventive concepts. FIGS. 5A, 5B, 5C, and 5D illustrate cross-sectional views respectively taken along lines A-A′, B-B′, C-C′, and D-D′ of FIG. 4.

Referring to FIGS. 4, 5A, 5B, 5C, and 5D, a single height cell SHC may be provided on a substrate 100. The single height cell SHC may include logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may include a first active region AR1 and a second active region AR2. Each of the first and second active regions AR1 and AR2 may extend in a second direction D2. For example, the first active region AR1 may be a PMOSFET region, and the second active region AR2 may be an NMOSFET region.

A first active pattern AP1 and a second active pattern AP2 may be defined by a trench TR formed on an upper portion of the substrate 100. The first active pattern AP1 may be provided on the first active region AR1, and the second active pattern AP2 may be provided on the second active region AR2. The first and second active patterns AP1 and AP2 may extend in the second direction D2. The substrate 100 may have portions that protrude in a third direction D3, and the first and second active patterns AP1 and AP2 may correspond to the protruding portions of the substrate 100.

A device isolation layer ST may be provided on the substrate 100. The device isolation layer ST may fill the trench TR. The device isolation layer ST may include, for example, silicon oxide. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3. The first, second, and third semiconductor patterns SP1, SP2, and SP3 may be sequentially positioned in a vertical direction (or the third direction D3). For example, the first, second, and third semiconductor patterns SP1, SP2, and SP3 of each of the first and second channel patterns CH1 and CH2 may be stacked to be spaced apart from each other.

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon, for example, single crystalline silicon. In some example embodiments, the first, second, and third semiconductor patterns SP1, SP2, and SP3 may be nano-sheets.

A plurality of first source/drain patterns SD1 may be provided on the first active pattern AP1. A plurality of first recesses RS1 may be formed on an upper portion of the first active pattern AP1. The first source/drain patterns SD1 may be positioned in the first recesses RS1, respectively. The first source/drain patterns SD1 may be impurity areas having a first conductivity type (e.g., p-type). The first channel pattern CH1 may be positioned between the first source/drain patterns SD1 that are adjacent to each other in the second direction D2. For example, the first, second, and third semiconductor patterns SP1, SP2, and SP3 that are stacked to be spaced apart from each other may connect to each other the first source/drain patterns SD1 that are adjacent to each other in the second direction D2.

A plurality of second source/drain patterns SD2 may be provided on the second active pattern AP2. A plurality of second recesses RS2 may be formed on an upper portion of the second active pattern AP2. The second source/drain patterns SD2 may be positioned in the second recesses RS2, respectively. The second source/drain patterns SD2 may be impurity areas having a second conductivity type (e.g., n-type). The second channel pattern CH2 may be positioned between the second source/drain patterns SD2 that are adjacent to each other in the second direction D2. For example, the first, second, and third semiconductor patterns SP1, SP2, and SP3 that are stacked spaced apart from each other may connect to each other the second source/drain patterns SD2 that are adjacent to each other in the second direction D2.

The first and second source/drain patterns SD1 and SD2 may be epitaxial patterns formed by a selective epitaxial growth (SEG) process. For example, each of the first and second source/drain patterns SD1 and SD2 may have a top surface (e.g., a portion of the top surface) higher than a top surface of the third semiconductor pattern SP3. In some example embodiments, the top surface of at least one of the first and second source/drain patterns SD1 and SD2 may be located at substantially the same level as that of the top surface of the third semiconductor pattern SP3.

For example, the first source/drain patterns SD1 may include a semiconductor element (e.g., SiGe) whose lattice constant is greater than that of a semiconductor element (e.g., Si) of the substrate 100. Thus, the first source/drain patterns SD1 that are adjacent to each other in the second direction D2 may provide the first channel pattern CH1 therebetween with a compressive stress. In some example embodiments, the second source/drain patterns SD2 may include the same semiconductor element (e.g., Si) as that of the substrate 100.

The first source/drain pattern SD1 may have an uneven embossing shape at a sidewall thereof. For example, the sidewall of the first source/drain pattern SD1 may have a wavy profile. The sidewall of the first source/drain pattern SD1 may protrude toward a gate electrode GE which will be discussed below.

Gat electrodes GE may be provided on the first and second channel patterns CH1 and CH2. Each of the gate electrodes GE may extend in a first direction D1, while running across the first and second channel patterns CH1 and CH2. Each of the gate electrodes GE may vertically overlap a corresponding one of the first and second channel patterns CH1 and CH2. The gate electrodes GE may be spaced apart from each other in the second direction D2.

Portions of each of the gate electrodes GE may be positioned between the first, second, and third semiconductor patterns SP1, SP2, and SP3. For example, a transistor according to some example embodiments of the present embodiment may be a three-dimensional field effect transistor (e.g., multibridge-channel metal-oxide-semiconductor field-effect transistor (MBCFET) or gate-all-around field-effect transistor (GAAFET)), in which the gate electrode GE three-dimensionally surrounds the first and second channel patterns CH1 and CH2.

On the second active region AR2, inner spacers ISP may be provided between the gate electrodes GE and the second source/drain pattern SD2. Each of the gate electrodes GE may be spaced apart from the second source/drain pattern SD2 across the inner spacers ISP. The inner spacers ISP may mitigate or prevent leakage current from the gate electrode GE.

A pair of gate spacers GS may be provided on opposite sidewalls of the gate electrode GE on the third semiconductor pattern SP3. The gate spacers GS may extend in the first direction D1 along the gate electrode GE. For example, the gate spacers GS may include at least one selected from SiCN, SiCON, and SiN. In some example embodiments, the gate spacers GS may include a multiple layer formed of at least two selected from SiCN, SiCON, and SiN. The gate spacer GS may include, for example, a silicon-containing dielectric material. The gate spacer GS may serve as an etch stop layer when active contacts AC are formed in a subsequent process. The gate spacer GS may cause the active contacts AC to be formed in a self-alignment manner.

A gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be provided between the gate electrodes GE and the first channel pattern CH1 and between the gate electrodes GE and the second channel pattern CH2. The gate dielectric layer GI may surround each of the first, second, and third semiconductor patterns SP1, SP2, and SP3. The gate dielectric layer GI may cover a top surface of the device isolation layer ST that underlies the gate electrodes GE. For example, the gate dielectric layer GI may include one or more of a silicon oxide layer, a silicon oxynitride layer, and a high-k dielectric layer. In some example embodiments, the gate dielectric layer GI may include a multiple layer formed of a silicon oxide layer and a high-k dielectric layer.

For example, a semiconductor devices according to some example embodiments of the present inventive concepts may include a negative capacitance (NC) field effect transistor (FET) that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, at least one selected from hafnium oxide, hafnium zirconium oxide, barium strontium titanium oxide, and lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The kind of impurities included in the ferroelectric material layer may depend on a ferroelectric material included in the ferroelectric material layer.

When the ferroelectric material layer includes hafnium oxide, the ferroelectric material layer may include at least one of impurities such as gadolinium (Gd), silicon (Si), zirconium (Zr), aluminum (Al), and yttrium (Y).

When the impurities are aluminum (Al), the ferroelectric material layer may include about 3 to about 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to 80 atomic percent zirconium.

The paraelectric material layer may have paraelectric properties. The paraelectric material layer may include, for example, at least one selected from silicon oxide and metal oxide that has a high dielectric constant. The metal oxide included in the paraelectric material layer may include, for example, at least one selected from hafnium oxide, zirconium oxide, and aluminum oxide, but the present inventive concepts are not limited thereto.

The ferroelectric and paraelectric material layers may include the same material. The ferroelectric material layer may have ferroelectric properties, but the paraelectric material layer may not have ferroelectric properties. When the ferroelectric material layer and a paraelectric material include hafnium oxide, a crystal structure of hafnium oxide included in the ferroelectric material layer may be different from that of hafnium oxide included in the paraelectric material layer.

The ferroelectric material layer may have a thickness having ferroelectric properties. The thickness of the ferroelectric material layer may range, for example, from about 0.5 nm to about 10 nm, but the present inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include one ferroelectric material layer. For another example, the gate dielectric layer GI may include a plurality of ferroelectric material layers that are spaced apart from each other. The gate dielectric layer GI may have a structure in which a plurality of ferroelectric material layers and a plurality of paraelectric material layers are alternately stacked.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS.

A second interlayer dielectric layer 120 may be disposed on the first interlayer dielectric layer 110. A third interlayer dielectric layer 130 may be provided on the second interlayer dielectric layer 120. A fourth interlayer dielectric layer 140 may be provided on the third interlayer dielectric layer 130. For example, the first, second, third, and fourth interlayer dielectric layers 110, 120, 130, and 140 may include a silicon oxide layer.

The single height cell SHC may have a first boundary BD1 and a second boundary BD2 that are opposite to each other in the second direction D2. Each of the first and second boundaries BD1 and BD2 may extend in the first direction D1. The single height cell SHC may have a third boundary BD3 and a fourth boundary BD4 that are opposite to each other in the first direction D1. Each of the third and fourth boundaries BD3 and BD4 may extend in the second direction D2.

The single height cell SHC may be provided on its opposite sides with a pair of separation structures DB that are opposite to each other in the second direction D2. For example, the pair of separation structures DB may be provided on the first and second boundaries BD1 and BD2 of the single height cell SHC, correspondingly. The separation structure DB may extend in the first direction D1 parallel to the gate electrodes GE.

The separation structure DB may penetrate the first and second interlayer dielectric layers 110 and 120 to extend into the first and second active patterns AP1 and AP2. The separation structure DB may penetrate an upper portion of each of the first and second active patterns AP1 and AP2. The separation structure DB may electrically separate an active region of the single height cell SHC from an active region of an adjacent another cell.

Active contacts AC may be provided to penetrate the first interlayer dielectric layer 110 and the second interlayer dielectric layer 120. Each of the active contacts AC may be electrically connected to a corresponding one of the first and second source/drain patterns SD1 and SD2. The gate electrodes GE may be positioned between the active contacts AC that are adjacent to each other in the second direction D2. When viewed in plan, each of the active contacts AC may have a bar shape that extends in the first direction D1.

Each of the active contacts AC may include a conductive pattern and a barrier pattern that surrounds the conductive pattern. The barrier pattern may cover sidewalls and a bottom surface of the conductive pattern. For example, the conductive pattern may include at least one metal selected from aluminum, copper, tungsten, molybdenum, and cobalt. The barrier pattern may include either a metal layer including at least one selected from titanium, tantalum, tungsten, nickel, cobalt, and platinum or a metal nitride layer including at least one selected from titanium nitride (TiN), tantalum nitride (TaN), tungsten nitride (WN), nickel nitride (NiN), cobalt nitride (CoN), and platinum nitride (PtN).

The active contact AC may be a self-aligned contact. For example, the gate capping pattern GP and the gate spacer GS may be used to form the active contact AC in a self-alignment manner. The active contact AC may be disposed adjacent to a sidewall of the gate spacer GS. In some example embodiments, the active contact AC may cover a portion of the top surface of the gate capping pattern GP.

A metal-semiconductor compound layer SC may be provided between the active contacts AC and the first and second source/drain patterns SD1 and SD2. Each of the active contacts AC may be electrically connected through the metal-semiconductor compound layer SC to a corresponding one of the first and second source/drain patterns SD1 and SD2. For example, the metal-semiconductor compound layer SC may include at least one selected from titanium silicide, tantalum silicide, tungsten silicide, nickel silicide, and cobalt silicide.

A gate contact GC may be provided to penetrate the second interlayer dielectric layer 120 and the gate capping pattern GP to come into electrical connection with the gate electrode GE. The gate contact GC may include a conductive pattern and a barrier pattern that surrounds the conductive pattern. The barrier pattern may cover sidewalls and a bottom surface of the conductive pattern. For example, the gate contact GC may have a substantially the same structure as that of the active contact AC. When viewed in plan, the gate contact GC may be disposed overlapping the first active region AR1 and the second active region AR2. For example, the gate contact GC may be provided on the first active pattern AP1.

A first metal layer M1 may be provided in the third interlayer dielectric layer 130. For example, the first metal layer M1 may include a first power line M1_R1, a second power line M1_R2, and first wiring lines M1_I. The lines M1_R1, M1_R2, and M1_I of the first metal layer M1 may extend in parallel to each other in the second direction D2.

For example, the first and second power lines M1_R1 and M1_R2 may be respectively provided on the third and fourth boundaries BD3 and BD4 of the single height cell SHC. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first and second power lines M1_R1 and M1_R2. The first wiring lines M1_I of the first metal layer M1 may be spaced apart from each other in the first direction D1. Each of the first wiring lines M1_I may have a line-width less than that of each of the first and second power lines M1_R1 and M1_R2.

The first metal layer M1 may further include first vias VI1. The first vias VI1 may be provided underneath the lines M1_R1, M1_R2, and M1_I of the first metal layer M1. The active contacts AC and the gate contact GC may be electrically connected through the first vias VI1 to certain lines of the first metal layer M1.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. The second wiring lines M2_I may extend in the first direction D1 to be parallel with each other and may be spaced apart from each other in the second direction D2.

The second metal layer M2 may further include second vias VI2 that are correspondingly provided underneath the second wiring lines M2_I. A certain line of the first metal layer M1 may be electrically through the second via VI2 to a corresponding line of the second metal layer M2. A certain line and its underlying second via VI2 of the second metal layer M2 may be simultaneously formed in a dual damascene process.

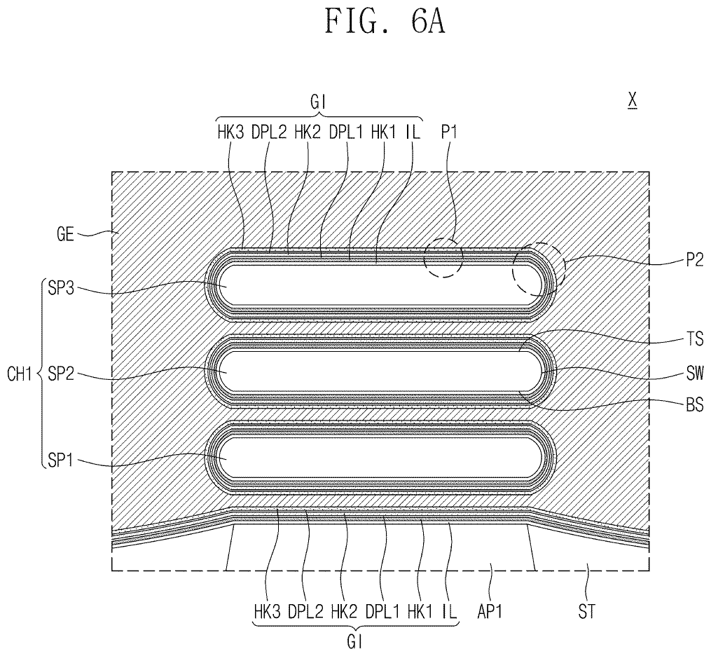

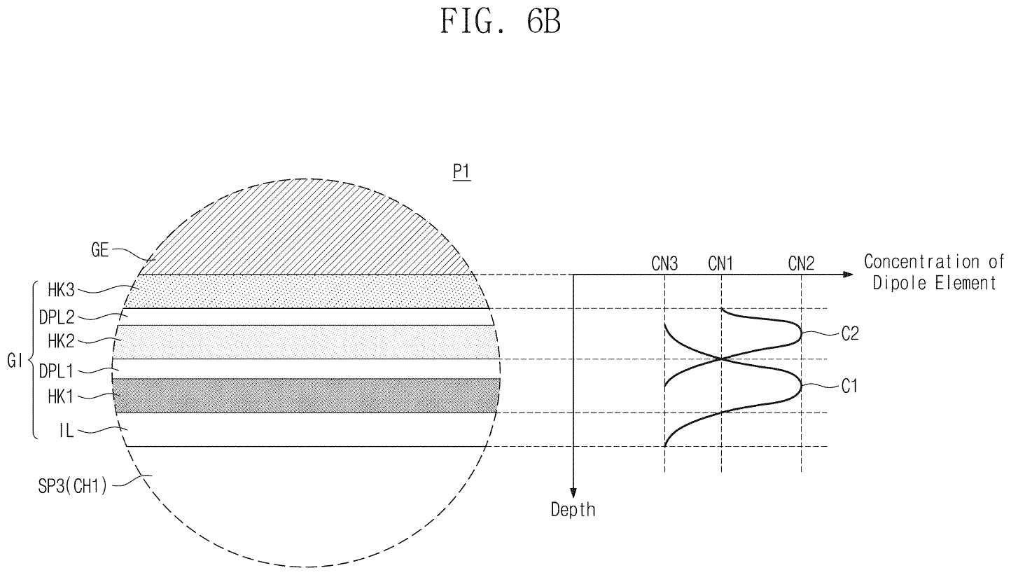

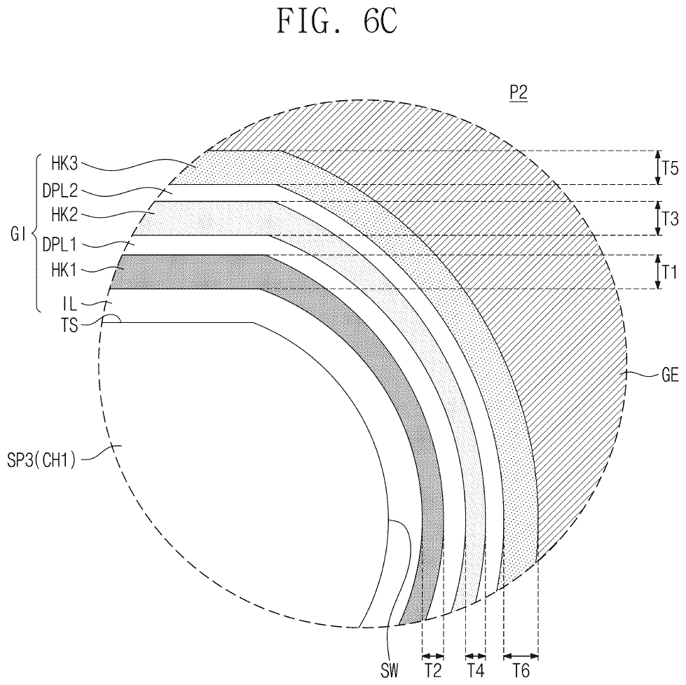

FIG. 6A illustrates an enlarged view of section X of FIG. 5D. FIGS. 6B and 6C illustrate enlarged views showing sections P1 and P2 of FIG. 6A, respectively.

Referring to FIGS. 6A, 6B, and 6C, the following description will focus on the gate electrode GE, the first channel pattern CH1, and the gate dielectric layer GI on the first active region AR1. The gate dielectric layer GI may cover a surface of each of the first, second, and third semiconductor patterns SP1, SP2, and SP3 of the first channel pattern CH1. The gate dielectric layer GI may include an interface layer IL, a first high-k dielectric layer HK1, a first dipole layer DPL1, a second high-k dielectric layer HK2, a second dipole layer DPL2, and a third high-k dielectric layer HK3. The interface layer IL, the first high-k dielectric layer HK1, the first dipole layer DPL1, the second high-k dielectric layer HK2, the second dipole layer DPL2, and the third high-k dielectric layer HK3 of the gate dielectric layer GI may be sequentially disposed on each of the first, second, and third semiconductor patterns SP1, SP2, and SP3.

The interface layer IL may have a uniform thickness to cover the surface of each of the first, second, and third semiconductor patterns SP1, SP2, and SP3. The interface layers IL may be in direct contact with the first, second, and third semiconductor patterns SP1, SP2, and SP3. For example, the interface layer IL may be a component of the gate dielectric layer GI most adjacent to the first, second, and third semiconductor patterns SP1, SP2, and SP3. The thickness of the interface layer IL may be less than that of each of the first, second, and third high-k dielectric layers HK1, HK2, and HK3.

The first dipole layer DPL1 may be positioned between the first high-k dielectric layer HK1 and the second high-k dielectric layer HK2. The second dipole layer DPL2 may be positioned between the second high-k dielectric layer HK2 and the third high-k dielectric layer HK3. The first dipole layer DPL1 may include an oxide of a first dipole element C1. The second dipole layer DPL2 may include an oxide of a second dipole element C2. For example, the first dipole layer DPL1 may include the first dipole element C1, and the second dipole layer DPL2 may include the second dipole element C2. The first and second dipole elements C1 and C2 may include lanthanum (La), aluminum (Al), or a combination thereof. For example, the first dipole element C1 may include lanthanum (La), and the second dipole element C2 may include aluminum (Al). In some example embodiments, the first dipole element C1 may include aluminum (Al), and the second dipole element C2 may include lanthanum (La). Aluminum (Al) may be a high work-function dipole, and lanthanum (La) may be a low work-function dipole.

Each of the first and second dipole layers DPL1 and DPL2 may have an excessively small thickness, and thus may not be observed in an electron microscope image. The first and second dipole layers DPL1 and DPL2 may diffuse the first and second dipole elements C1 and C2, respectively, into the gate dielectric layer GI. Thus, lanthanum (La), aluminum (Al), or a combination thereof may be contained as impurities in the gate dielectric layer GI. The first and second dipole elements C1 and C2 may allow the gate dielectric layer GI to have dipole boundaries between the first high-k dielectric layer HK1 and the interface layer IL and between the first high-k dielectric layer HK1 and the second high-k dielectric layer HK2.

The first dipole element C1 may have a first concentration CN1 in the first dipole layer DPL1. The first dipole element C1 may have a concentration that increases in a direction from the first dipole layer DPL1 to the first high-k dielectric layer HK1. In the first high-k dielectric layer HK1, the first dipole element C1 may have a second concentration CN2 as a maximum concentration. The concentration of the first dipole element C1 may decrease with decreasing distance from the interface layer IL and the second high-k dielectric layer HK2. The first dipole element C1 may have a third concentration CN3 as a minimum concentration in the interface layer IL and the second high-k dielectric layer HK2. For example, the first and second high-k dielectric layers HK1 and HK2 may include the first dipole element C1, but most of the first dipole element C1 may be present in the first high-k dielectric layer HK1. For another example, the second high-k dielectric layer HK2 may not include the first dipole element C1.

The second dipole element C2 may have a first concentration CN1 in the second dipole layer DPL2. The second dipole element C2 may have a concentration that increases in a direction from the second dipole layer DPL2 to the second high-k dielectric layer HK2. In the second high-k dielectric layer HK2, the second dipole element C2 may have a second concentration CN2 as a maximum concentration. The concentration of the second dipole element C2 may decrease as approaching the first high-k dielectric layer HK1 and the third high-k dielectric layer HK3. The second dipole element C2 may have a third concentration CN3 as a minimum concentration in the first high-k dielectric layer HK1. For example, the first and second high-k dielectric layers HK1 and HK2 may include the second dipole element C2, but most of the second dipole element C2 may be present in the second high-k dielectric layer HK2. For another example, the first high-k dielectric layer HK1 may not include the second dipole element C2.

Unlike the first and second high-k dielectric layers HK1 and HK2, the third high-k dielectric layer HK3 may not include any of the first and second dipole elements C1 and C2, but the present inventive concepts are not limited thereto.

The first and second dipole elements C1 and C2 may control an effective work function of the gate electrode GE. When the first and second dipole elements C1 and C2 include lanthanum (La), the gate electrode GE may have a reduced effective work function. When the first and second dipole elements C1 and C2 include aluminum (Al), the gate electrode GE may have an increased effective work function. When the first and second dipole elements C1 and C2 include different elements from each other, an effective work function of the gate electrode GE may be adjusted in detail. For example, an effective work function of the gate electrode GE may be adjusted depending on kinds of the first and second dipole elements C1 and C2. Therefore, it may be possible to variously and easily adjust a threshold voltage of a transistor on the first active region AR1.

The first, second, and third high-k dielectric layers HK1, HK2, and HK3 may include a material whose dielectric constant is greater than that of a silicon oxide layer. The first, second, and third high-k dielectric layers HK1, HK2, and HK3 may each include a high-k dielectric material. For example, the first, second, and third high-k dielectric layers HK1, HK2, and HK3 may include the same high-k dielectric material. In some example embodiments, the first, second, and third high-k dielectric layers HK1, HK2, and HK3 may include different high-k dielectric materials from each other. In some example embodiments, one high-k dielectric layer among the first, second, and third high-k dielectric layers HK1, HK2, and HK3, may include a different high-k dielectric material from the other two high-k dielectric layers.

For example, the high-k dielectric material may include at least one selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

According to an example embodiment, the first, second, and third high-k dielectric layers HK1, HK2, and HK3 may include fluorine (F), nitrogen (N), or a combination thereof. For example, among the first, second, and third high-k dielectric layers HK1, HK2, and HK3, one may include nitrogen (N), another may include fluorine (F), and the remainder may not include nitrogen (N) and fluorine (F). For example, nitrogen (N) and fluorine (F) may reduce oxygen defects of the first, second, and third high-k dielectric layers HK1, HK2, and HK3.

The first and second high-k dielectric layers HK1 and HK2 may not have a uniform thickness. For example, each of the first and second high-k dielectric layers HK1 and HK2 may have different thicknesses on a top surface TS and a lateral surface SW of the third semiconductor pattern SP3. The first high-k dielectric layer HK1 may have a first thickness T1 on the top surface TS of the third semiconductor pattern SP3 and a second thickness T2 on the lateral surface SW of the third semiconductor pattern SP3. The second high-k dielectric layer HK2 may have a third thickness T3 on the top surface TS of the third semiconductor pattern SP3 and a fourth thickness T4 on the lateral surface SW of the third semiconductor pattern SP3. The first thickness T1 may be greater than the second thickness T2, and the third thickness T3 may be greater than the fourth thickness T4. The first thickness T1 may be substantially the same as the third thickness T3, and the second thickness T2 may be substantially the same as the fourth thickness T4. A thickness of each of the first and second high-k dielectric layers HK1 and HK2 may be thinner on lateral surfaces SW of the first, second, and third semiconductor patterns SP1, SP2, and SP3 than on top surfaces TS and bottom surfaces BS of the first, second, and third semiconductor patterns SP1, SP2, and SP3.

Unlike the first and second high-k dielectric layers HK1 and HK2, the third high-k dielectric layer HK3 may have a uniform thickness. For example, a fifth thickness T5 of the third high-k dielectric layer HK3 on the top surface TS of the third semiconductor pattern SP3 may be substantially the same as a sixth thickness T6 of the third high-k dielectric layer HK3 on the lateral surface SW of the third semiconductor pattern SP3. In addition, the fifth thickness T5 and the sixth thickness T6 may each be substantially the same as the first thickness T1 and the third thickness T3.

In this configuration, the third high-k dielectric layer HK3 may cause that the gate dielectric layer GI on the lateral surfaces SW of the first, second, and third semiconductor patterns SP1, SP2, and SP3 may have a thickness sufficient enough to allow a flow of a gate current. Thus, the gate current may flow adjacent to the lateral surfaces SW of the first, second, and third semiconductor patterns SP1, SP2, and SP3. Accordingly, a semiconductor device may improve in electrical characteristics.

According to an example embodiment, the gate electrode GE, the second channel pattern CH2, and the gate dielectric layer GI on the second active region AR2 may have structures substantially the same as those of the gate electrode GE, the first channel pattern CH1, and the gate dielectric layer GI on the first active region AR1, respectively.

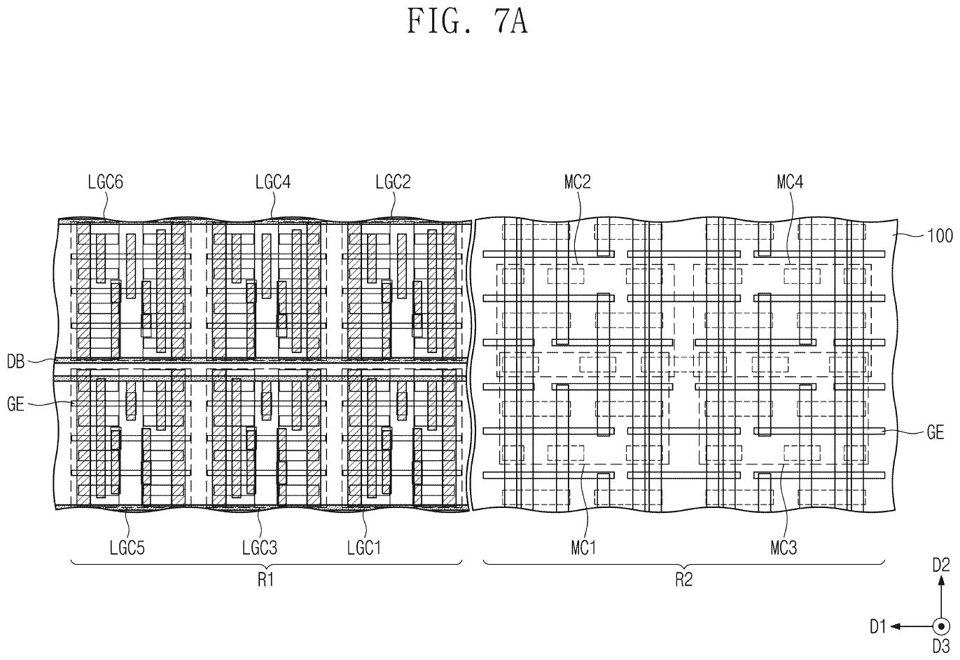

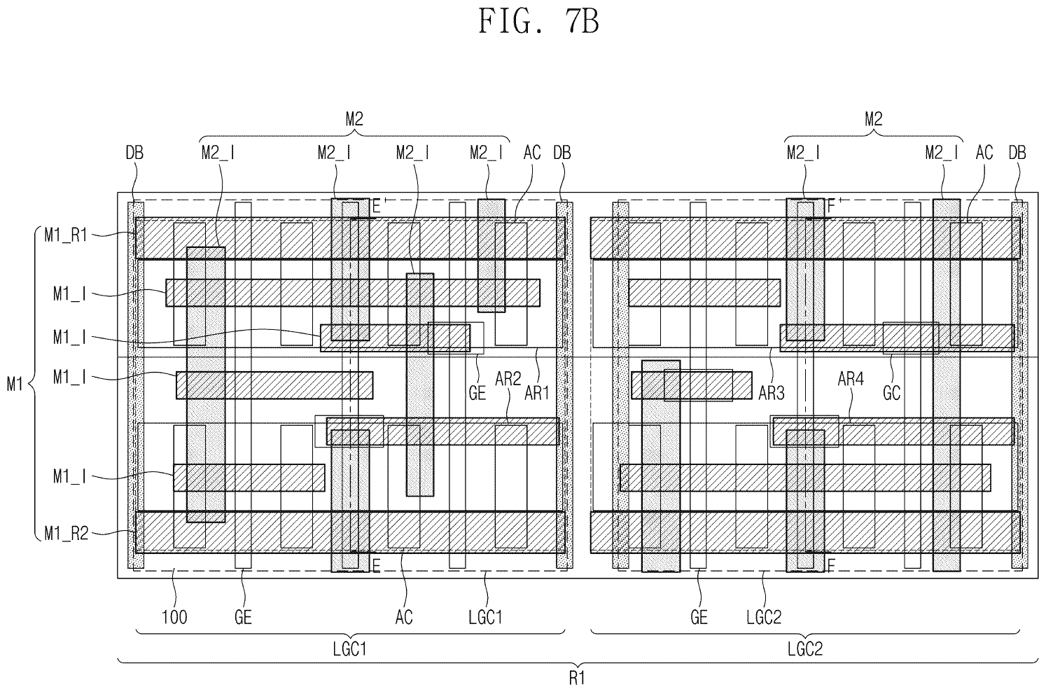

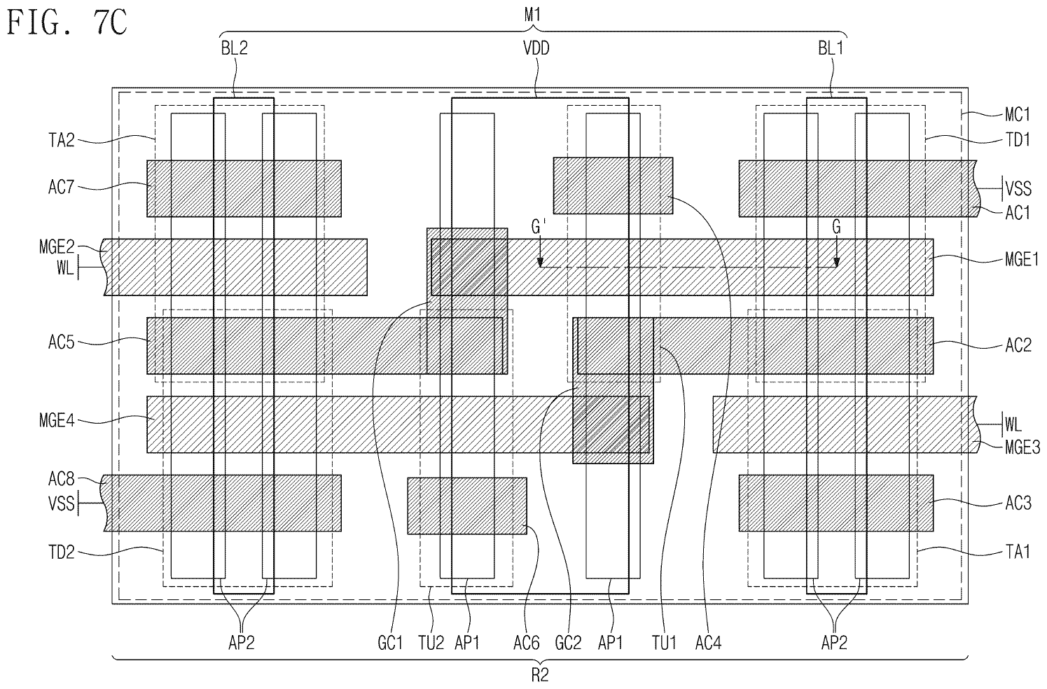

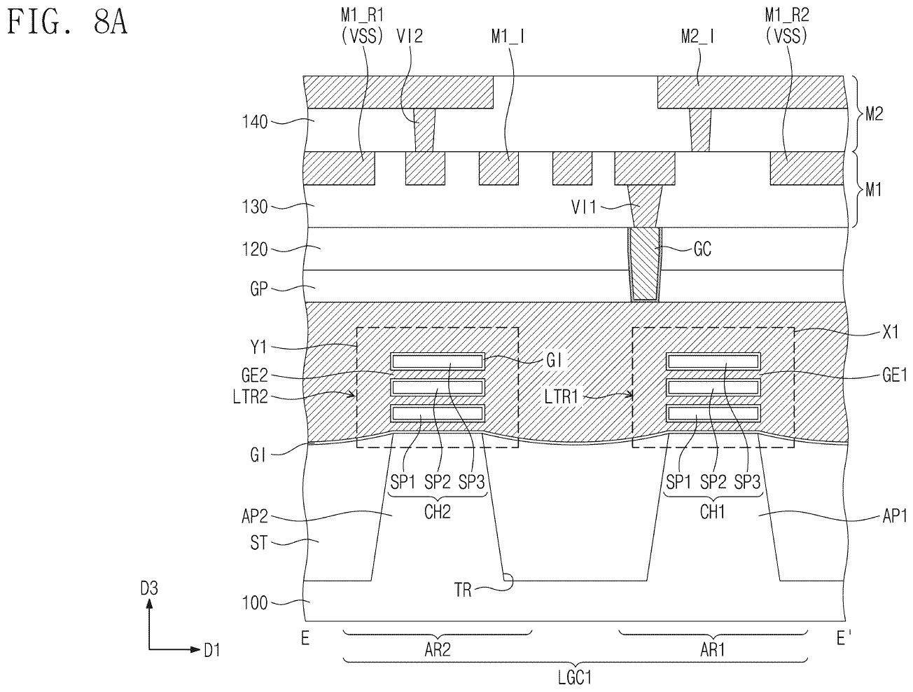

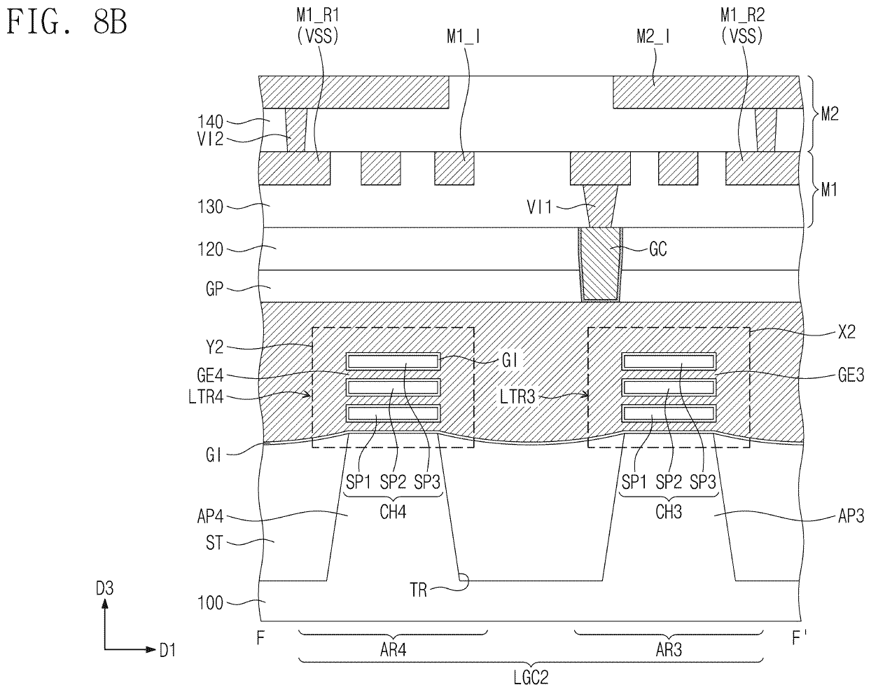

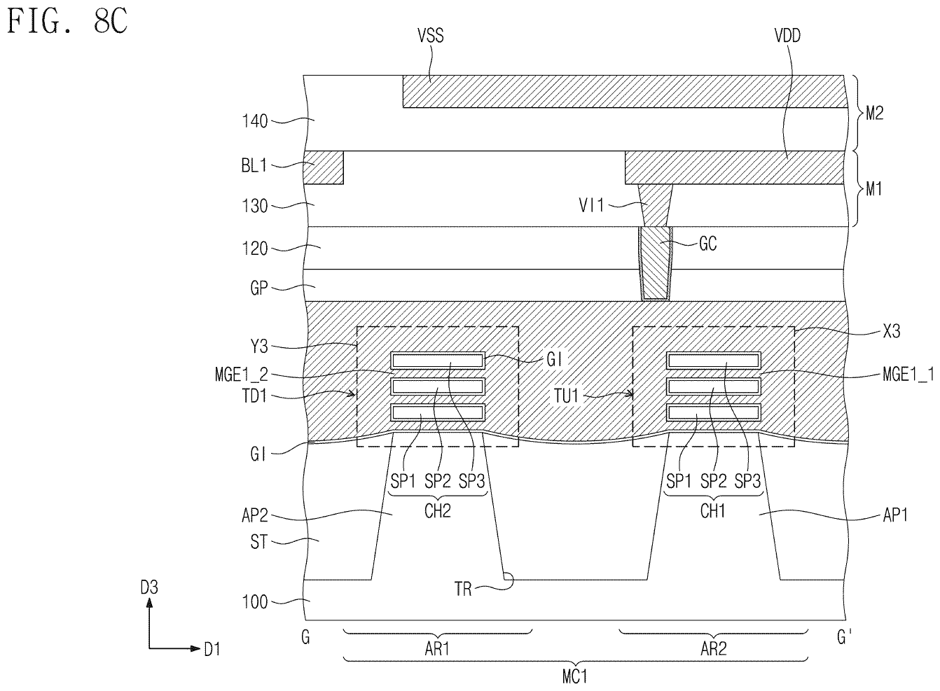

FIGS. 7A, 7B, and 7C illustrate plan views showing a semiconductor device according to some example embodiments of the present inventive concepts. FIGS. 8A, 8B, and 8C illustrate cross-sectional views respectively taken along line E-E′ of FIG. 7B, line F-F′ of FIG. 7B, and line G-G′ of FIG. 7C.

Referring to FIG. 7A, a substrate 100 may be provided to include a first region R1 and a second region R2. The first region R1 and the second region R2 may be spaced apart from each other in a first direction D1. For example, the first region R1 may be a logic area where a logic circuit is present. The second region R2 may be a memory area where a memory circuit is present.

The first region R1 may be provided thereon with first, second, third, fourth, fifth, and sixth logic cells LGC1, LGC2, LGC3, LGC4, LGC5, and LGC6. The first, second, third, fourth, fifth, and sixth logic cells LGC1, LGC2, LGC3, LGC4, LGC5, and LGC6 may be two-dimensionally arranged along the first and second directions D1 and D2. The first, second, third, fourth, fifth, and sixth logic cells LGC1, LGC2, LGC3, LGC4, LGC5, and LGC6 may be spaced apart from each other, but the present inventive concepts are not limited thereto. For example, the first, second, third, fourth, fifth, and sixth logic cells LGC1, LGC2, LGC3, LGC4, LGC5, and LGC6 may partially overlap another adjacent logic cell.

The second region R2 may be provided thereon with first, second, third, and fourth memory cells MC1, MC2, MC3, and MC4. The first, second, third, and fourth memory cells MC1, MC2, MC3, and MC4 may be two-dimensionally arranged along the first and second directions D1 and D2. The first memory cell MC1 may overlap a portion of the second memory cell MC2 and the third memory cell MC3 may overlap a portion of the fourth memory cell MC4, but the present inventive concepts are not limited thereto. For example, the first, second, third, and fourth memory cells MC1, MC2, MC3, and MC4 may be spaced apart from each other.

Referring to FIGS. 7A, 7B, 8A, and 8B, the first logic cell LGC1 and the second logic cell LGC2 may be areas that are spaced apart from each other in a semiconductor device. Each of the first and second logic cells LGC1 and LGC2 may be provided with logic transistors included in a logic circuit. The first logic cell LGC1 may include first and second logic transistors LTR1 and LTR2. The second logic cell LGC2 may include third and fourth logic transistors LTR3 and LTR4. The first and second logic transistors LTR1 and LTR2 may have their threshold voltages less than the third and fourth logic transistors LTR3 and LTR4. For example, the first logic cell LGC1 may be a Vt area on which logic transistors having relatively low threshold voltages are disposed. The second logic cell LGC2 may be a Vt area on which logic transistors having relatively high threshold voltages are disposed.

The first logic cell LGC1 may include a first active region AR1 and a second active region AR2. The first and second active regions AR1 and AR2 may be spaced apart from each other in the first direction D1. For example, the first active region AR1 may be a PMOSFET region, and the second active region AR2 may be an NMOSFET region.

The second logic cell LGC2 may include a third active region AR3 and a fourth active region AR4. The third and fourth active regions AR3 and AR4 may be spaced apart from each other in the first direction D1. For example, the third active region AR3 may be a PMOSFET region, and the fourth active region AR4 may be an NMOSFET region.

A trench TR formed on an upper portion of the substrate 100 may define a first active pattern AP1, a second active pattern AP2, a third active pattern AP3, and a fourth active pattern AP4. The first, second, third, and fourth active patterns AP1, AP2, AP3, and AP4 may be provided on the first, second, third, and fourth active regions AR1, AR2, AR3, and AR4, respectively. The first, second, third, and fourth active patterns AP1, AP2, AP3, and AP4 may extend in the second direction D2. The first, second, third, and fourth active patterns AP1, AP2, AP3, and AP4 may be vertically protruding portions of the substrate 100.

The trench TR may be filled with a device isolation layer ST. The device isolation layer ST may include a silicon oxide layer. The device isolation layer ST may not cover any of first, second, third, and fourth channel patterns CH1, CH2, CH3, and CH4 which will be discussed below.

A first channel pattern CH1, a second channel pattern CH2, a third channel pattern CH3, and a fourth channel pattern CH4 may be provided on the first active pattern AP1, the second active pattern AP2, the third active pattern AP3, and the fourth active pattern AP4, respectively. Each of the first, second, third, and fourth channel patterns CH1, CH2, CH3, and CH4 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

The first logic cell LGC1 may be provided thereon with gate electrodes GE that extend in the first direction D1 and run across the first and second channel patterns CH1 and CH2. Each of the gate electrodes GE may vertically overlap the first and second channel patterns CH1 and CH2. The second logic cell LGC2 may be provided thereon with gate electrodes GE that extend in the first direction D1 and run across the third and fourth channel patterns CH3 and CH4. Each of the gate electrodes GE may vertically overlap the third and fourth channel patterns CH3 and CH4.

The gate electrodes GE may include a first gate electrode GE1 on the first channel pattern CH1, a second gate electrode GE2 on the second channel pattern CH2, a third gate electrode GE3 on the third channel pattern CH3, and a fourth gate electrode GE4 on the fourth channel pattern CH4.

A gate capping pattern GP may be provided on the gate electrode GE. The gate capping pattern GP may extend in the first direction D1 along the gate electrode GE. The gate capping pattern GP may include a material having an etch selectivity to a second interlayer dielectric layer 120 which will be discussed below. For example, the gate capping pattern GP may include at least one selected from SiON, SiCN, SiCON, and SiN.

A gate dielectric layer GI may be provided between each of the first, second, third, and fourth gate electrodes GE1, GE2, GE3, and GE4 and each of the first, second, third, and fourth channel patterns CH1, CH2, CH3, and CH4. The gate dielectric layer GI may cover a top surface, a bottom surface, and opposite sidewalls of each of the first, second, and third semiconductor patterns SP1, SP2, and SP3. The gate dielectric layer GI may cover a top surface of the device isolation layer ST below the gate electrode GE.

Each of the first and second logic cells LGC1 and LGC2 may be provided on its opposite sides with a pair of separation structures DB that are opposite to each other in the second direction D2. The separation structure DB may extend in the first direction D1 parallel to the gate electrodes GE.

The gate capping pattern GP may be sequentially provided thereon with second, third, and fourth interlayer dielectric layers 120, 130, and 140. A gate contact GC may be provided to penetrate the second interlayer dielectric layer 120 and the gate capping pattern GP to come into electrical connection with the gate electrode GE. A first metal layer M1 may be provided in the third interlayer dielectric layer 130, and a second metal layer M2 may be provided in the fourth interlayer dielectric layer 140.

Consequently, each of the first, second, third, fourth, fifth, and sixth logic cells LGC1, LGC2, LGC3, LGC4, LGC5, and LGC6 may have a structure substantially the same as that of the single height cell SHC discussed with reference to FIGS. 4 and 5A to 5D.

Referring to FIGS. 7A, 7C, and 8C, a first memory cell MC1 may be provided on the second region R2 of the substrate 100. The first memory cell MC1 may include one pair of first active patterns AP1 and two pairs of second active patterns AP2. First, second, third, and fourth memory gate electrodes MGE1, MGE2, MGE3, and MGE4 may be provided to extend in the first direction D1, while running across the first and second active patterns AP1 and AP2. The first, second, third, and fourth memory gate electrodes MGE1, MGE2, MGE3, and MGE4 may vertically overlap the first and second channel patterns CH1 and CH2. The first memory gate electrode MGE1 may be symmetric with the fourth memory gate electrode MGE4, and the second memory gate electrode MGE2 may be symmetric with the third memory gate electrode MGE3.

The second memory gate electrode MGE2 and the fourth memory gate electrode MGE4 may extend in the first direction D1 and be parallel with each other in the second direction D2. The second memory gate electrode MGE2 and the fourth memory gate electrode MGE4 may be spaced apart and electrically insulated from each other. The first memory gate electrode MGE1 and the third memory gate electrode MGE3 may extend in the first direction D1 and be parallel with each other in the second direction D2. The first memory gate electrode MGE1 and the third memory gate electrode MGE3 may be spaced apart and electrically insulated from each other.

Memory transistors may be constituted by the first and second active patterns AP1 and AP2 and the first, second, third, and fourth memory gate electrodes MGE1, MGE2, MGE3, and MGE4. The first memory cell MC1 may include memory cell transistors including a first pull-up transistor TU1, a first pull-down transistor TD1, a second pull-up transistor TU2, a second pull-down transistor TD2, a first pass-gate transistor TA1, and the second pass-gate transistor TA2. For example, one of the two pairs of second active patterns AP2 may constitute a body of the first pass-gate transistor TA1 and a body of the first pull-down transistor TD1. Another of the two pairs of second active patterns AP2 may constitute a body of the second pass-gate transistor TA2 and a body of the second pull-down transistor TD2. One of the one pair of first active patterns AP1 may constitute a body of the first pull-up transistor TU1. Another of the one pair of first active patterns AP1 may constitute a body of the second pull-up transistor TU2. The first and second pull-up transistors TU1 and TU2 may be positive metal oxide semiconductor (PMOS) transistors. The first and second pull-down transistors TD1 and TD2 and the first and second pass-gate transistors TA1 and TA2 may be negative metal oxide semiconductor (NMOS) transistors.

The first memory gate electrode MGE1 may be a common gate of the first pull-down and pull-up transistors TD1 and TU1. The second memory gate electrode MGE2 may be a gate of the second pass-gate transistor TA2. The third memory gate electrode MGE3 may be a gate of the first pass-gate transistor TA1. The fourth memory gate electrode MGE4 may be a common gate of the first pull-down and pull-up transistors TD2 and TU2.

There may be provided first to eighth active patterns AC1 to AC8, first and second gate contacts GC1 and GC2, first and second bit lines BL1 and BL2, a power line VDD, and a ground line VSS. The first active contact AC1 may be electrically connected to the first pull-down transistor TD1 and the ground line VSS. The second active contact AC2 may be electrically connected to the first pull-down transistor TD1, the first pass-gate transistor TA1, and the first pull-up transistor TU1. The third active contact AC3 may be electrically connected to the first pass-gate transistor TA1 and the first bit line BL1. The fourth active contact AC4 may be electrically connected to the first pull-up transistor TU1 and the power line VDD. The fifth active contact AC5 may be electrically connected to the second pull-up transistor TU2, the second pull-down transistor TD2, and the second pass-gate transistor TA2. The sixth active contact AC6 may be electrically connected to the second pull-up transistor TU2 and the power line VDD. The seventh active contact AC7 may be electrically connected to the second pass-gate transistor TA2 and the second bit line BL2. The eighth active contact AC8 may be electrically connected to the second pull-down transistor TD2 and the ground line VSS.

The first gate contact GC1 may electrically connect the fifth active contact AC5 to the first memory gate electrode MGE1. The second gate contact GC2 may electrically connect the second active contact AC2 to the fourth memory gate electrode MGE4. For example, the first pull-up transistor TU1 and the first pull-down transistor TD1 may constitute a first inverter. The second pull-up transistor TU2 and the second pull-down transistor TD2 may constitute a second inverter. The first and second inverters may be connected to constitute a latch structure. The first pass-gate transistor TA1 may be connected to the first inverter and the first bit line BL1. The second pass-gate transistor TA2 may be connected to the second inverter and the second bit line BL2. The first and second pass-gate transistors TA1 and TA2 may have their gates electrically connected to a word line WL. Thus, the first memory cell MC1 may be implemented as a static random access memory (SRAM) cell.

The first channel pattern CH1 may be provided on the first active pattern AP1. The second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3. The first, second, and third semiconductor patterns SP1, SP2, and SP3 may be sequentially positioned in a vertical direction (or the third direction D3). In this configuration, the first, second, and third semiconductor patterns SP1, SP2, and SP3 of each of the first and second channel patterns CH1 and CH2 may be stacked spaced apart from each other.

The first memory gate electrode MGE1 may include a 1_1st memory gate electrode MGE1_1 on the first channel pattern CH1 and a 1_2nd memory gate electrode MGE1_2 on the second channel pattern CH2.

The second, third, and fourth memory gate electrodes MGE2, MGE3, and MGE4 may each have a structure substantially the same as that of the first memory gate electrode MGE1. For example, the memory transistors of the first memory cell MC1 may be three-dimensional field effect transistors (e.g., MBCFET or GAAFET) in which the first, second, third, and fourth memory gate electrodes MGE1, MGE2, MGE3, and MGE4 three-dimensionally surround channels. The memory transistors of the first memory cell MC1 may have structures substantially the same as the logic transistors discussed with reference to FIGS. 5A to 5D, 8A, and 8B, and this may hold true for the second, third, and fourth memory cells MC2, MC3, and MC4.

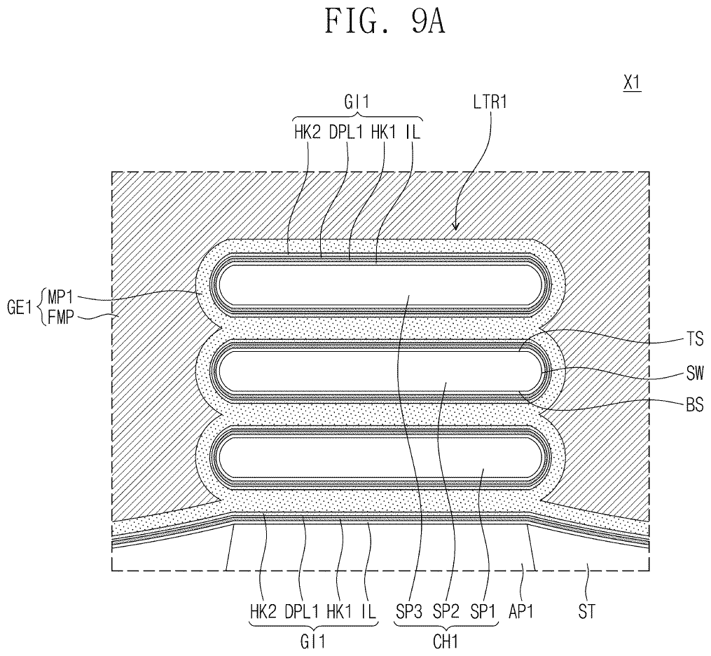

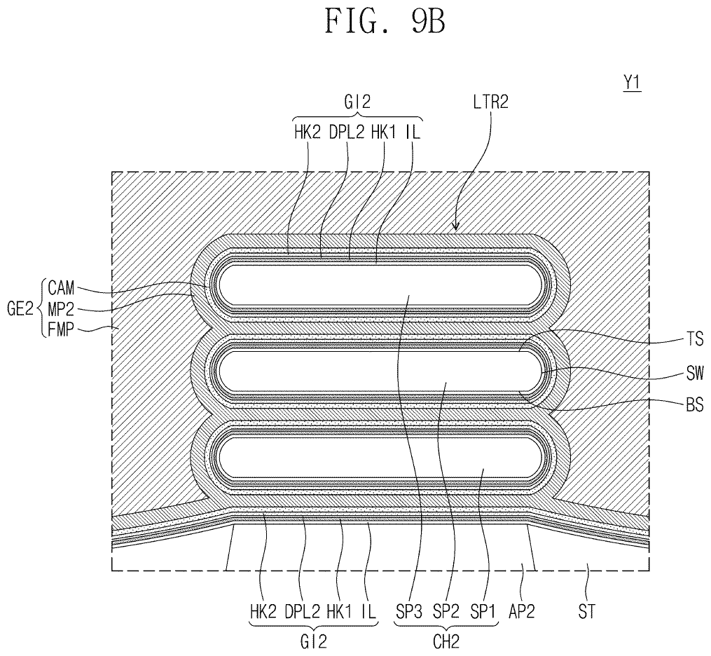

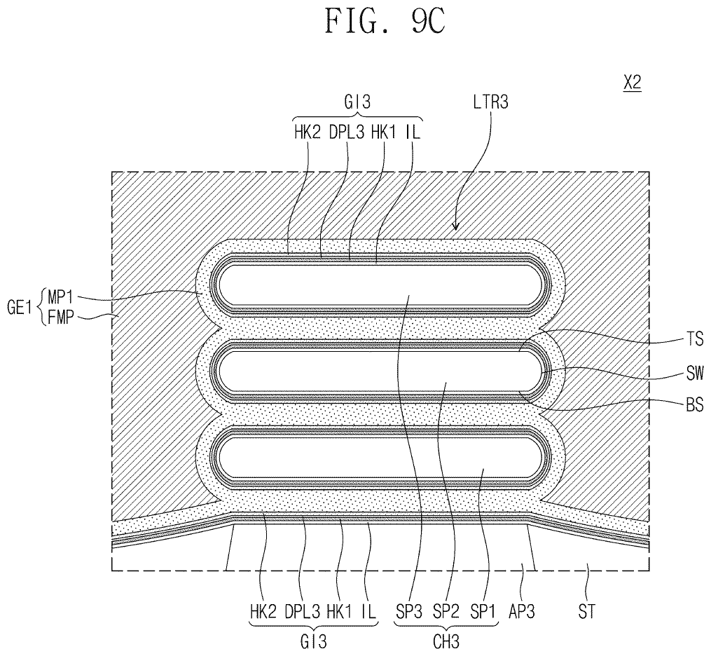

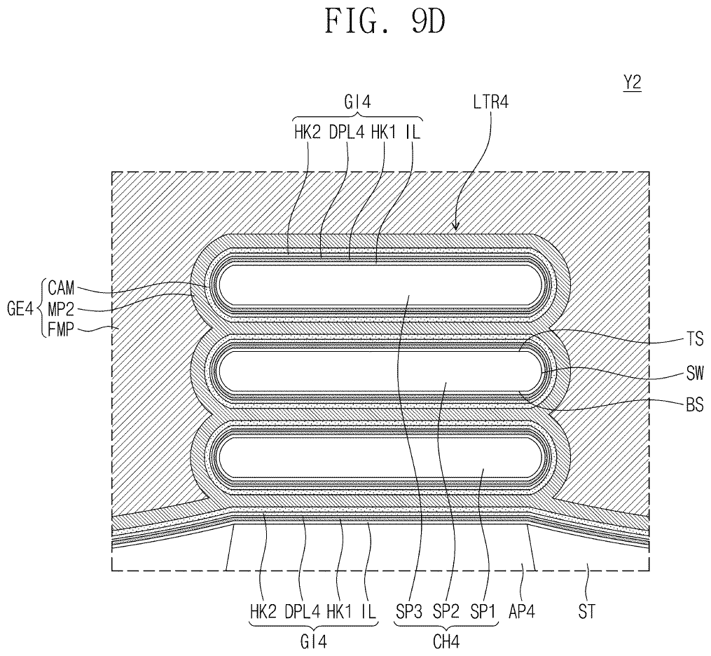

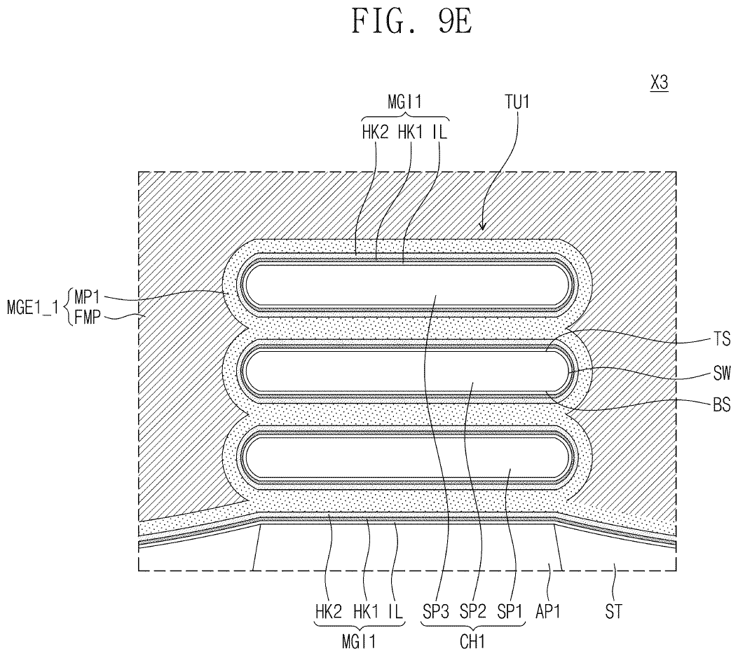

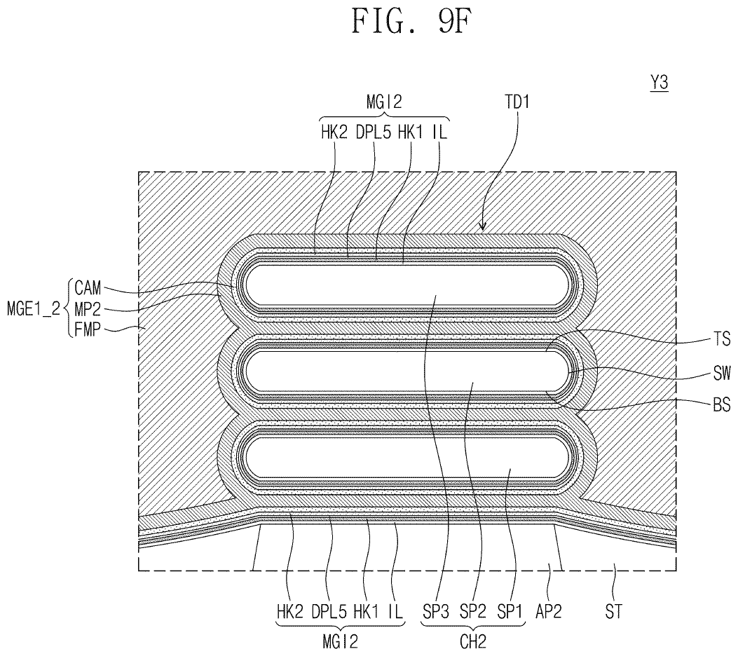

FIGS. 9A and 9B illustrate enlarged views showing sections X1 and Y1 of FIG. 8A, respectively. FIGS. 9C and 9D illustrate enlarged views showing sections X2 and Y2 of FIG. 8B, respectively. FIGS. 9E and 9F illustrate enlarged views showing sections X3 and Y3 of FIG. 8C, respectively.

Referring to FIGS. 9A and 9B, the first and second logic transistors LTR1 and LTR2 will be discussed in detail. The first logic transistor LTR1 may include a first gate electrode GE1, a first channel pattern CH1, and a first gate dielectric layer GI1. The second logic transistor LTR2 may include a second gate electrode GE2, a second channel pattern CH2, and a second gate dielectric layer GI2.

The first gate dielectric layer GI1 may cover a surface of each of the first, second, and third semiconductor patterns SP1, SP2, and SP3 of the first channel pattern CH1. The second gate dielectric layer GI2 may cover a surface of each of the first, second, and third semiconductor patterns SP1, SP2, and SP3 of the second channel pattern CH2. The first gate dielectric layer GI1 may include an interface layer IL, and may also include a first high-k dielectric layer HK1, a first dipole layer DPL1, and a second high-k dielectric layer HK2 that are sequentially disposed on the interface layer IL. The second gate dielectric layer GI2 may include an interface layer IL, and may also include a first high-k dielectric layer HK1, a second dipole layer DPL2, and a second high-k dielectric layer HK2 that are sequentially disposed on the interface layer IL. The first dipole layer DPL1 may include a first dipole element, and the second dipole layer DPL2 may include a second dipole element. The first and second dipole layers DPL1 and DPL2 may diffuse the first and second dipole elements into the first and second gate dielectric layers GI1 and GI2, respectively. For example, as discussed with reference to FIGS. 6A and 6B, the first high-k dielectric layer HK1 of the first gate dielectric layer GI1 may include the first dipole element, and the first high-k dielectric layer HK1 of the second gate dielectric layer GI2 may include the second dipole element.

The first gate electrode GE1 may include a first metal pattern MP1 and a fill metal pattern FMP on the first metal pattern MP1. The first metal pattern MP1 may fill between the first, second, and third semiconductor patterns SP1, SP2, and SP3 of the first channel pattern CH1, while covering the first, second, and third semiconductor patterns SP1, SP2, and SP3 of the first channel pattern CH1. For example, a portion of the first metal pattern MP1 may be positioned between the first, second, and third semiconductor patterns SP1, SP2, and SP3 of the first channel pattern CH1.

The first metal pattern MP1 may include a first work function metal that adjusts a threshold voltage of a transistor. A composition of metal in the first work function metal may be adjusted to achieve a target threshold voltage of a transistor. For example, the first work function metal may be a p-type work function metal whose work function is relatively high.

The first metal pattern MP1 may include a metal nitride layer. The first metal pattern MP1 may include nitrogen (N) and at least one metal selected from titanium (Ti), tantalum (Ta), niobium (Nb), aluminum (Al), tungsten (W), and molybdenum (Mo). For example, the first metal pattern MP1 may include a titanium nitride (TiN) layer, a tantalum nitride (TaN) layer, a titanium oxynitride (TiON) layer, a titanium silicon nitride (TiSiN) layer, a titanium aluminum nitride (TiAlN) layer, a tungsten carbon nitride (WCN) layer, or a molybdenum nitride (MoN) layer. In some example embodiments, the first metal pattern MP1 may include metal oxynitride, metal oxycarbide, or metal oxynitride carbide. In this case, the metal may be selected from titanium (Ti), tantalum (Ta), niobium (Nb), aluminum (Al), tungsten (W), and molybdenum (Mo) discussed above.

The first metal pattern MP1 may be covered with the fill metal pattern FMP of the first gate electrode GE1. For example, the fill metal pattern FMP of the first gate electrode GE1 may not be provided between the first, second, and third semiconductor patterns SP1, SP2, and SP3. The first metal pattern MP1 may separate the fill metal pattern FMP from the first gate dielectric layer GI1.

The second gate electrode GE2 may cover the second gate dielectric layer GI2. The second gate electrode GE2 may include a capping pattern CAM, a second metal pattern MP2, and a fill metal pattern FMP that are sequentially stacked. For example, the first gate electrode GE1 and the second gate electrode GE2 may share one fill metal pattern FMP.

In the second gate electrode GE2, the capping pattern CAM may be a capping layer provided between the second gate dielectric layer GI2 and the second metal pattern MP2. The capping pattern CAM may have a uniform thickness that covers the second gate dielectric layer GI2. The capping pattern CAM may be positioned on top surfaces TS, bottom surfaces BS, and lateral surfaces SW of the first, second, and third semiconductor patterns SP1, SP2, and SP3 of the second channel pattern CH2. For example, the capping pattern CAM may have a profile similar to that of the second gate dielectric layer GI2. The capping pattern CAM may include a metal nitride layer. For example, the capping pattern CAM may include nitrogen (N) and at least one metal selected from titanium (Ti), tantalum (Ta), aluminum (Al), tungsten (W), and molybdenum (Mo). For example, the capping pattern CAM may include TiN.

The second metal pattern MP2 may cover the capping pattern CAM and fill a space between the first, second, and third semiconductor patterns SP1, SP2, and SP3 of the second channel pattern CH2. For example, a portion of the second metal pattern MP2 may be positioned between the first, second, and third semiconductor patterns SP1, SP2, and SP3 of the second channel pattern CH2. The fill metal pattern FMP may be positioned on the second metal pattern MP2.

The second metal pattern MP2 may include a second work function metal that adjusts a threshold voltage of a transistor. A composition of metal in the second work function metal may be adjusted to achieve a target threshold voltage of a transistor. For example, the second work function metal may be an n-type work function metal whose work function is relatively low.

The second metal pattern MP2 may include metal carbide. The second metal pattern MP2 may include metal carbide doped with (or containing) silicon and/or aluminum. For example, the second metal pattern MP2 may include aluminum-doped titanium carbide (TiAlC), aluminum-doped tantalum carbide (TaAlC), aluminum-doped vanadium carbide (VAlC), silicon-doped titanium carbide (TiSiC), or silicon-doped tantalum carbide (TaSiC). For another example, the second metal pattern MP2 may include aluminum-silicon-doped titanium carbide (TiAlSiC) or aluminum-silicon-doped tantalum carbide (TaAlSiC). For another example, the second metal pattern MP2 may include aluminum-doped titanium (TiAl). For another example, the second metal pattern MP2 may include metal nitride doped with silicon and/or aluminum, such as aluminum-doped titanium nitride (TiAlN).

The fill metal pattern FMP of the first and second gate electrodes GE1 and GE2 may have a resistance less than those of the first and second metal patterns MP1 and MP2. For example, the fill metal pattern FMP may include at least one low-resistance metal, such as aluminum (Al), tungsten (W), titanium (Ti), and tantalum (Ta).

According to an example embodiment, the first logic transistor LTR1 may be a PMOS transistor, and the second logic transistor LTR2 may be an NMOS transistor. The first dipole element may include aluminum (Al), and the second dipole element may include lanthanum (La). In this case, the first dipole element may increase an effective work function of the first gate electrode GE1, and the second dipole element may decrease an effective work function of the second gate electrode GE2. Thus, the first and second logic transistors LTR1 and LTR2 may have reduced threshold voltages.

Referring to FIGS. 9C and 9D, the third and fourth logic transistors LTR3 and LTR4 will be discussed in detail. The third logic transistor LTR3 may include a third gate electrode GE3, a third channel pattern CH3, and a third gate dielectric layer GI3. The fourth logic transistor LTR4 may include a fourth gate electrode GE4, a fourth channel pattern CH4, and a fourth gate dielectric layer GI4.

The third gate dielectric layer GI3 may cover a surface of each of the first, second, and third semiconductor patterns SP1, SP2, and SP3 of the third channel pattern CH3, and the fourth gate dielectric layer GI4 may cover a surface of each of the first, second, and third semiconductor patterns SP1, SP2, and SP3 of the fourth channel pattern CH4. The third gate dielectric layer GI3 may include an interface layer IL, and may also include a first high-k dielectric layer HK1, a third dipole layer DPL3, and a second high-k dielectric layer HK2 that are sequentially disposed on the interface layer IL. The fourth gate dielectric layer GI4 may include an interface layer IL, and may also include a first high-k dielectric layer HK1, a fourth dipole layer DPL4, and a second high-k dielectric layer HK2 that are sequentially disposed on the interface layer IL. The third dipole layer DPL3 may include a third dipole element, and the fourth dipole layer DPL4 may include a fourth dipole element. Like the first and second gate dielectric layers GI1 and GI2, the first high-k dielectric layer HK1 of the third gate dielectric layer GI3 may include the third dipole element, and the first high-k dielectric layer HK1 of the fourth gate dielectric layer GI4 may include the fourth dipole element.

The third gate electrode GE3 may include a first metal pattern MP1 and a fill metal pattern FMP on the first metal pattern MP1. For example, the third gate electrode GE3 may have substantially the same structure as that of the first gate electrode GE1, and may include substantially the same material as that of the first gate electrode GE1.

The fourth gate electrode GE4 may include a capping pattern CAM, a second metal pattern MP2, and a fill metal pattern FMP that are sequentially stacked. For example, the fourth gate electrode GE4 may have substantially the same structure as that of the second gate electrode GE2, and may include substantially the same material as that of the second gate electrode GE2. The third gate electrode GE3 and the fourth gate electrode GE4 may share one fill metal pattern FMP.

According to an example embodiment, the third logic transistor LTR3 may be a PMOS transistor, and the fourth logic transistor LTR4 may be an NMOS transistor. The third dipole element may include lanthanum (La), and the fourth dipole element may include aluminum (Al). In this case, the third dipole element may decrease an effective work function of the third gate electrode GE3, and the fourth dipole element may increase an effective work function of the fourth gate electrode GE4. Thus, the third and fourth logic transistors LTR3 and LTR4 may have increased threshold voltages.

Referring to FIGS. 9E and 9F, the first pull-up and pull-down transistors TU1 and TD1 will be discussed in detail. The first pull-up transistor TU1 may include a 1_1st memory gate electrode MGE1_1, a first channel pattern CH1, and a first memory gate dielectric layer MGI1. The first pull-down transistor TD1 may include a 1_2nd memory gate electrode MGE1_2, a second channel pattern CH2, and a second memory gate dielectric layer MGI2.

The first and second memory gate dielectric layers MGI1 and MGI2 may cover surfaces of the first, second, and third semiconductor patterns SP1, SP2, and SP3 of the first and second channel patterns CH1 and CH2, respectively. The first memory gate dielectric layer MGI1 may include an interface layer IL, and may also include a first high-k dielectric layer HK1 and a second high-k dielectric layer HK2 that are sequentially disposed on the interface layer IL. The second memory gate dielectric layer MGI2 may include an interface layer IL, and may also include a first high-k dielectric layer HK1, a fifth dipole layer DPL5, and a second high-k dielectric layer HK2 that are sequentially disposed on the interface layer IL. The fifth dipole layer DPL5 may include a fifth dipole element. Like the first, second, third, and fourth gate dielectric layers GI1, GI2, GI3, and GI4, the first high-k dielectric layer HK1 of the second memory gate dielectric layer MGI2 may include a fifth dipole element. However, the first memory gate dielectric layer MGI1 may include no dipole element.

The 1_1st memory gate electrode MGE1_1 may include a first metal pattern MP1 and a fill metal pattern FMP on the first metal pattern MP1. The 1_2nd memory gate electrode MGE1_2 may include a capping pattern CAM, a second metal pattern MP2, and a fill metal pattern FMP that are sequentially stacked. The 1_1st memory gate electrode MGE1_1 and the 1_2nd memory gate electrode MGE1_2 may share one fill metal pattern FMP.

According to an example embodiment, the first pull-up transistor TU1 may be a PMOS transistor, and the first pull-down transistor TD1 may be an NMOS transistor. The fifth dipole element may include aluminum (Al). In this case, the fifth dipole element may increase an effective work function of the 1_2nd memory gate electrode MGE1_2. Thus, a threshold voltage of the first pull-down transistor TD1 may increase while the first pull-up transistor TU1 maintains its threshold voltage.

Referring back to FIGS. 9A to 9F, the logic transistors LTR1, LTR2, LTR3, and LTR4 and the memory transistors TD1 and TU1 may include different gate dielectric layers from each other. The gate dielectric layers may include different dipole elements from each other. Thus, the logic transistors LTR1, LTR2, LTR3, and LTR4 and the memory transistors TD1 and TU1 may have various threshold voltages. Accordingly, semiconductor devices of example embodiments of the present inventive concepts may have a multiple threshold voltage (multi-Vt).

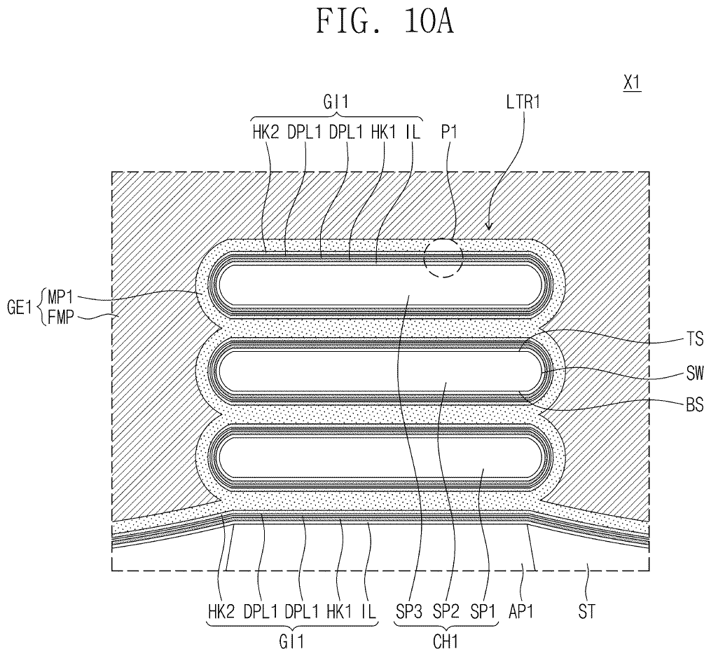

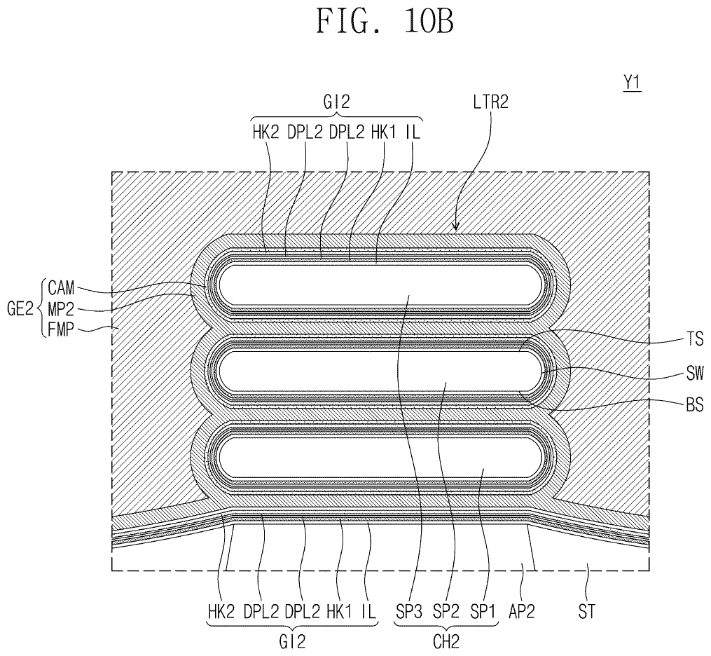

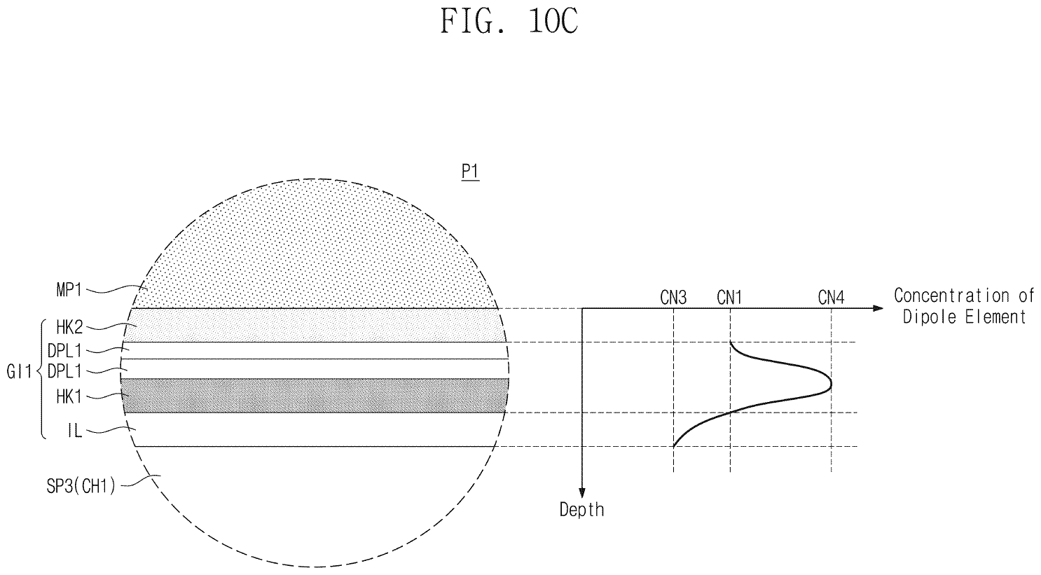

FIGS. 10A and 10B illustrate enlarged views showing sections X1 and Y1 of FIG. 8A, respectively. FIG. 10C illustrates an enlarged view showing section P1 of FIG. 10A.

Referring to FIGS. 10A, 10B, and 10C, the first gate dielectric layer GI1 of the first logic transistor LTR1 may include an interface layer IL, a first high-k dielectric layer HK1, a second high-k dielectric layer HK2, and two first dipole layers DPL1 between the first high-k dielectric layer HK1 and the second high-k dielectric layer HK2. The second gate dielectric layer GI2 of the second logic transistor LTR2 may include an interface layer IL, a first high-k dielectric layer HK1, a second high-k dielectric layer HK2, and two second dipole layers DPL2 between the first high-k dielectric layer HK1 and the second high-k dielectric layer HK2.

The first dipole layer DPL1 may include an oxide of a first dipole element. For example, the first dipole layer DPL1 may include the first dipole element. The first dipole element may include lanthanum (La), aluminum (Al), or a combination thereof. As the first dipole layer DPL1 diffuses the first dipole element into the first gate dielectric layer GI1, the first gate dielectric layer GI1 may contain lanthanum (La), aluminum (Al), or a combination thereof as an impurity. The first dipole element may cause the first gate dielectric layer GI1 to have a dipole boundary formed between the first high-k dielectric layer HK1 and the interface layer IL.

The first dipole element may have a first concentration CN1 in the first dipole layer DPL1 at an interface between the second high-k dielectric layer HK2 and the first dipole layer DPL1. The first dipole element may have a concentration that increases in a direction from the first dipole layer DPL1 to the first high-k dielectric layer HK1. In other words, the first dipole element may have a concentration that increases in the first high-k dielectric layer HK1 in a direction from the first dipole layer DPL1 to the interface layer IL. In the first high-k dielectric layer HK1, the first dipole element may have a fourth concentration CN4 as a maximum concentration. The fourth concentration CN4 may be greater than the second concentration CN2 of FIG. 6B. For example, the fourth concentration CN4 may be greater than the second concentration CN2 and less than twice the second concentration CN2. The concentration of the first dipole element may decrease as approaching the interface layer IL. The first dipole element may have a third concentration CN3 as a minimum concentration in the interface layer IL. The second high-k dielectric layer HK2 may not include the first dipole element, but the present inventive concepts are not limited thereto.

The second dipole layer DPL2 may include an oxide of a second dipole element, and the second gate dielectric layer GI2 may include the second dipole element. The second dipole element in the second gate dielectric layer GI2 may have a concentration profile substantially the same as that of the first dipole element in the first gate dielectric layer GI1. For example, the second dipole element may have a fourth concentration CN4 as a maximum concentration.

According to an example embodiment, the first logic transistor LTR1 may be a PMOS transistor, and the second logic transistor LTR2 may be an NMOS transistor. The first dipole element may include aluminum (Al), and the second dipole element may include lanthanum (La). The first and second dipole elements may have their concentrations greater than those of the first and second dipole elements of FIGS. 9A and 9B. Thus, the first and second logic transistors LTR1 and LTR2 may have threshold voltages less than those of the first and second logic transistors LTR1 and LTR2 depicted in FIGS. 9A and 9B, respectively.

In this example embodiments, two first dipole layers DPL1 and two second dipole layers DPL2 are illustrated, but the present inventive concepts are not limited thereto. For example, each of the first and second dipole layers DPL1 and DPL2 may be provided in three or more. In this case, a maximum concentration of each of the first and second dipole elements may be greater than the fourth concentration CN4. A dipole element concentration may be controlled depending on the number of dipole layers. In some example embodiments, the number of the first dipole layer DPL1 may be different from the number of the second dipole layer DPL2.

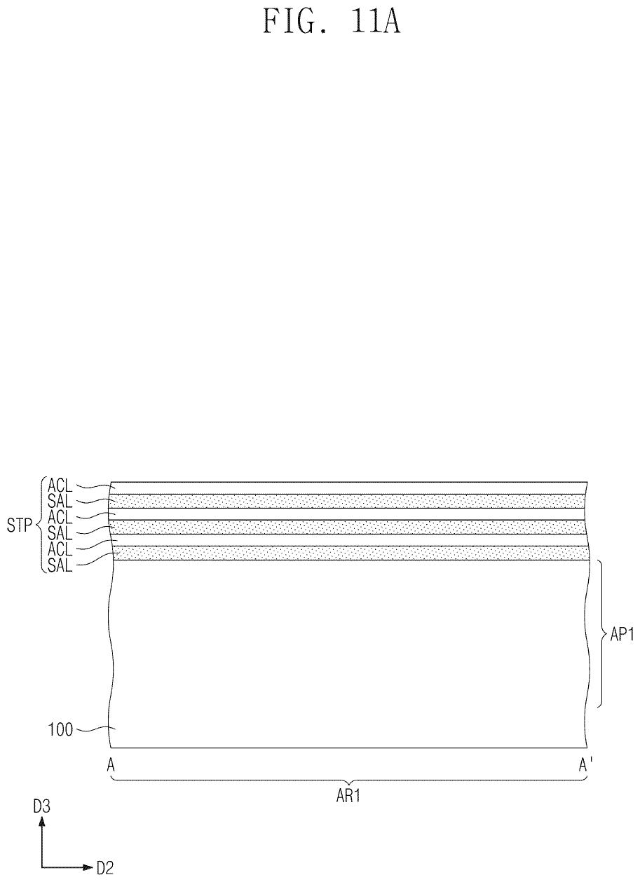

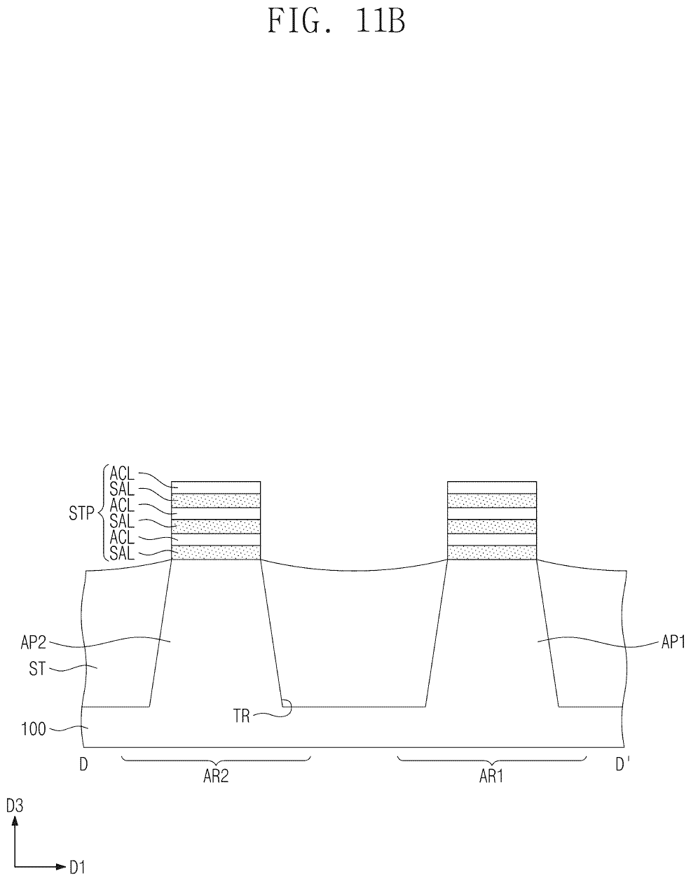

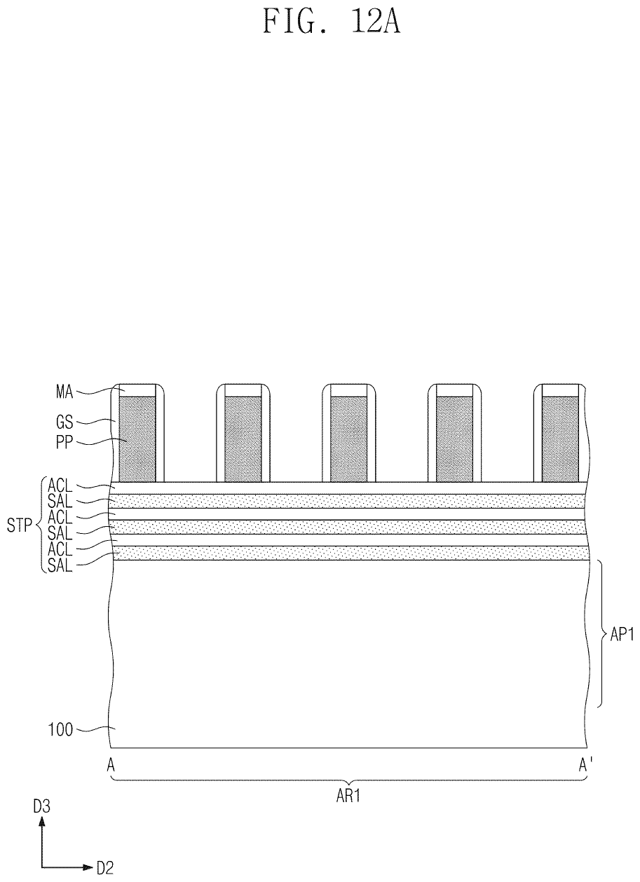

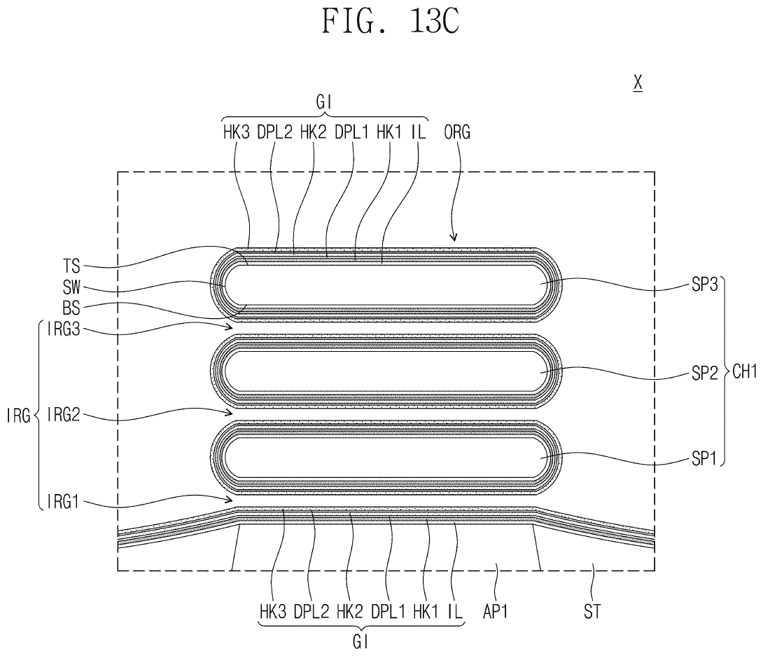

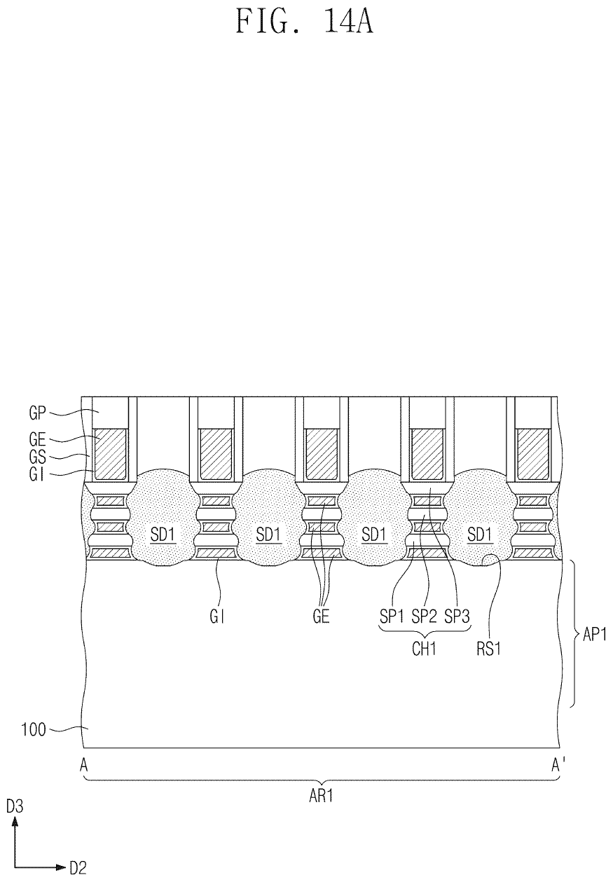

FIGS. 11A to 14B illustrate diagrams showing a method of fabricating a semiconductor device according to an example embodiment of the present inventive concepts. FIGS. 11A, 12A, 13A, and 14A illustrate cross-sectional views taken along line A-A′ of FIG. 4. FIGS. 11B, 12B, 13B, and 14B illustrate cross-sectional views taken along line D-D′ of FIG. 4. FIG. 13C illustrates an enlarged cross-sectional view showing section X of FIG. 13B.

Referring to FIGS. 11A, and 11B, a substrate 100 may be provided to include first and second active regions AR1 and AR2. Active layers ACL and sacrificial layers SAL may be alternately stacked on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe).

The sacrificial layers SAL may include a material having an etch selectivity with respect to the active layers ACL. For example, the active layers ACL may include silicon (Si), and the sacrificial layers SAL may include silicon-germanium (SiGe). The sacrificial layers SAL may each have a germanium concentration of about 10 at % to about 30 at %.

Mask patterns may be formed on the first and second active regions AR1 and AR2 of the substrate 100. The mask pattern may have a linear or bar shape that extends in a second direction D2.

The mask pattern may be used as an etching mask to perform a patterning process to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL that are alternately stacked. During the patterning process, the stack pattern STP may be formed simultaneously with the first and second active patterns AP1 and AP2.

A device isolation layer ST may be formed to fill the trench TR. For example, a dielectric layer may be formed on a front surface of the substrate 100 to cover the first and second active patterns AP1 and AP2 and the stack pattern STP. The dielectric layer may be recessed to form the device isolation layer ST until the stack pattern STP is exposed.

The device isolation layer ST may include a dielectric material, such as a silicon oxide layer. The stack pattern STP may be exposed upwardly from the device isolation layer ST. For example, the stack pattern STP may upwardly protrude in a vertical direction (e.g., a third direction D3) from the device isolation layer ST.

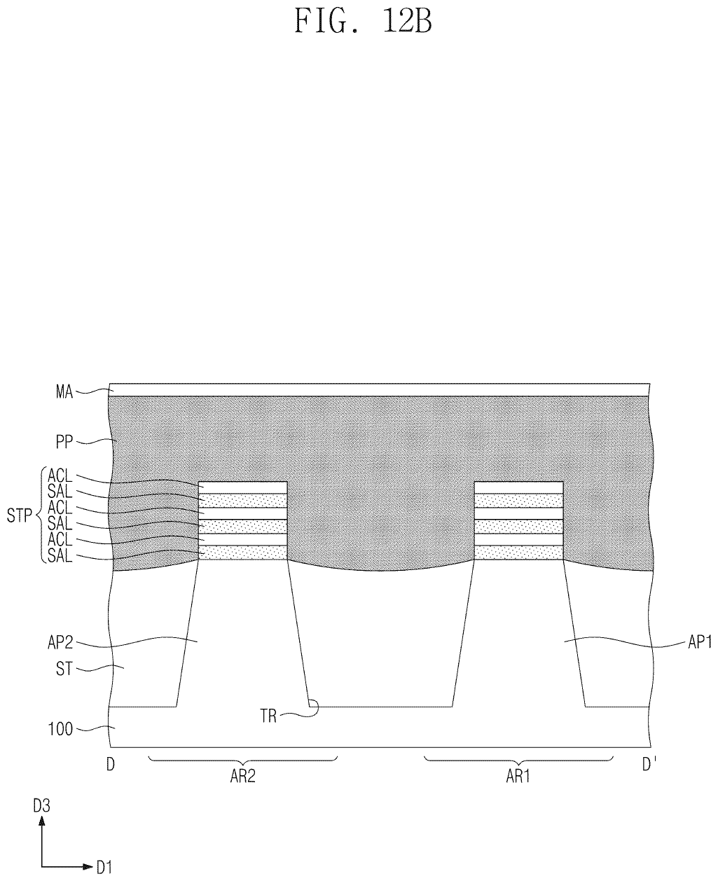

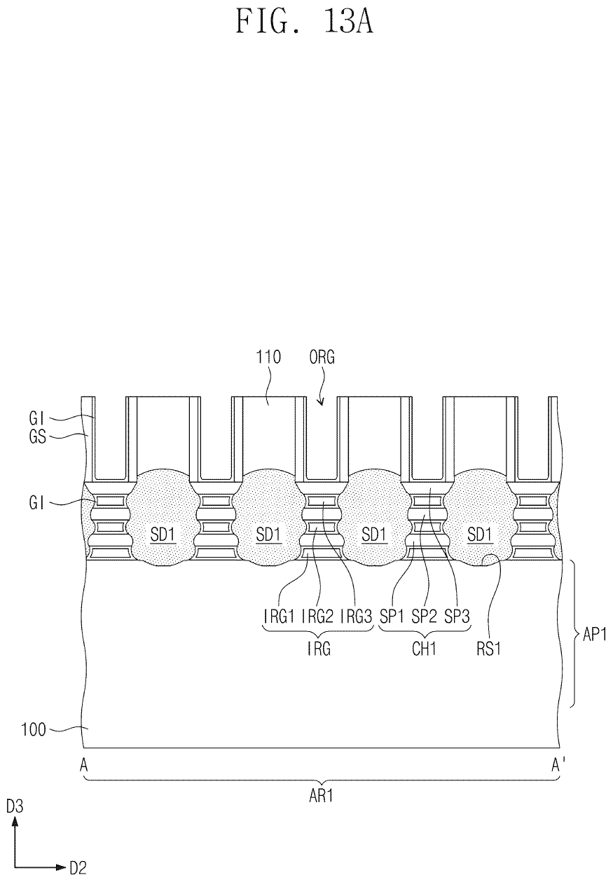

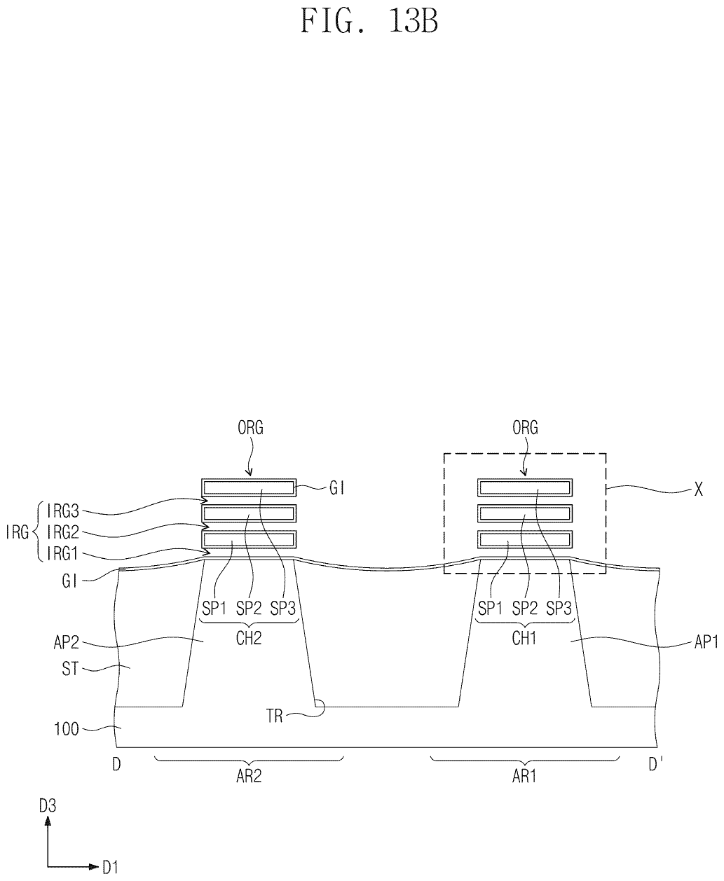

Referring to FIGS. 12A and 12B, sacrificial patterns PP may be formed on the substrate 100 to run across the stack pattern STP. Each of the sacrificial patterns PP may be formed to have a linear or bar shape that extends in a first direction D1. The sacrificial patterns PP may be spaced apart from each other in the second direction D2.

The formation of the sacrificial patterns PP may include forming a sacrificial layer on an the front surface of the substrate 100, forming hardmask patterns MA on the sacrificial layer, and using the hardmask patterns MA as an etching mask to pattern the sacrificial layer. The sacrificial layer may include polysilicon.

A pair of gate spacers GS may be formed on opposite sidewalls of each of the sacrificial patterns PP. The formation of the gate spacers GS may include conformally forming a gate spacer layer on the front surface of the substrate 100 and anisotropically etching the gate spacer layer. For example, the gate spacers GS may each be a multiple layer including at least two layers.

Referring to FIGS. 13A, 13B, and 13C, first recesses RS1 may be formed in the stack pattern STP on the first active pattern AP1. The formation of the first recesses RS1 may include using the hardmask patterns MA and the gate spacers GS as an etching mask to etch a portion of the stack pattern STP. Each of the first recess RS1 may be formed between a pair of sacrificial patterns PP.

The active layers ACL may be formed into first, second, and third semiconductor patterns SP1, SP2, and SP3 that are sequentially stacked between neighboring first recesses RS1. A first channel pattern CH1 may be constituted by the first, second, and third semiconductor patterns SP1, SP2, and SP3 between neighboring first recesses RS1.

A second channel pattern CH2 may be formed on the second active pattern AP2. The second channel pattern CH2 may include first, second, and third semiconductor patterns SP1, SP2, and SP3 that are sequentially stacked on the second active pattern AP2. The formation of the second channel pattern CH2 may be substantially the same as the formation of the first channel pattern CH1.

First source/drain patterns SD1 may be formed in corresponding ones of the first recesses RS1, respectively. For example, a selective epitaxial growth (SEG) process may be performed in which inner sidewalls of the first recesses RS1 are used as seeds layer to form epitaxial layers that fill the first recesses RS1. The epitaxial layers may grow from seeds, or the first, second, and third semiconductor patterns SP1, SP2, and SP3, the sacrificial layers SAL, and the substrate 100 that are exposed by the first recesses RS1. The SEG process may include chemical vapor deposition (CVD) or molecular beam epitaxy (MBE).

The first source/drain pattern SD1 may include a semiconductor element (e.g., SiGe) whose lattice constant is greater than that of a semiconductor element of the substrate 100. During the formation of the first source/drain pattern SD1, impurities (e.g., boron, gallium, or indium) may be in-situ implanted to allow the first source/drain pattern SD1 to have a p-type conductivity. Alternatively, after the formation of the first source/drain pattern SD1, impurities may be implanted into the first source/drain pattern SD1.

Afterwards, a first interlayer dielectric layer 110 may be formed on the front surface of the substrate 100. The first interlayer dielectric layer 110 may cover the first source/drain patterns SD1, the hardmask patterns MA, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be used to planarize the first interlayer dielectric layer 110. The hardmask patterns MA may all be removed during the planarization process. Thus, the first interlayer dielectric layer 110 may have a top surface coplanar with those of the sacrificial patterns PP and those of the gate spacers GS.

After the planarization process, the sacrificial patterns PP may be selectively removed. The removal of the sacrificial patterns PP may form an outer region ORG that exposes the first and second channel patterns CH1 and CH2. The removal of the sacrificial patterns PP may include performing a wet etching process using an etchant that selectively etches polysilicon.

The sacrificial layers SAL exposed through the outer region ORG may be selectively removed to form inner regions IRG. An etching process that selectively etches the sacrificial layers SAL may be used to remove only the sacrificial layers SAL while leaving the first, second, and third semiconductor patterns SP1, SP2, and SP3. The etching process may have a high etch rate for silicon-germanium (SiGe) having a relatively high germanium concentration. For example, the etching process may have a high etch rate with for silicon-germanium (SiGe) having a germanium concentration greater than about 10 at %. Thus, sacrificial layers SAL may be removed on the first and second active regions AR1 and AR2.

The removal of the sacrificial layers SAL may form first, second, and third inner regions IRG1, IRG3, and IRG3. The first inner region IRG1 may be formed between the first and second active patterns AP1 and AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

A gate dielectric layer GI may be formed on the first, second, and third semiconductor patterns SP1, SP2, and SP3 exposed by the first, second, and third inner regions IRG1, IRG2, and IRG3 and the outer region ORG. The gate dielectric layer GI may surround a surface of each of the first, second, and third semiconductor patterns SP1, SP2, and SP3. For example, the gate dielectric layer GI may be formed in the first, second, and third inner regions IRG1, IRG2, and IRG3 and the outer region ORG.

The formation of the gate dielectric layer GI may include sequentially forming an interface layer IL, a first high-k dielectric layer HK1, a first dipole layer DPL1, a second high-k dielectric layer HK2, a second dipole layer DPL2, and a third high-k dielectric layer HK3 on each of the first, second, and third semiconductor patterns SP1, SP2, and SP3.

The interface layer IL may be formed by performing an oxidation process or a deposition process on each of the first, second, and third semiconductor patterns SP1, SP2, and SP3. The formation of the interface layer IL may include performing one of chemical oxidation, O3 oxidation, millisecond oxidation, and atomic layer deposition (ALD). The interface layer IL may include, for example, a silicon oxide layer. The interface layer IL may be formed to have a thickness of about 1.0 nm to about 2.5 nm.

The first high-k dielectric layer HK1 may be formed on the interface layer IL. A deposition process, such as atomic layer deposition (ALD) or chemical vapor deposition (CVD), may be used to form the first high-k dielectric layer HK1 having a uniform thickness. The first high-k dielectric layer HK1 may include, for example, hafnium oxide, zirconium oxide, yttrium oxide, or a complex thereof. The first high-k dielectric layer HK1 may be formed to have a uniform thickness of about 0.5 nm to about 1.5 nm.

The first dipole layer DPL1 may be formed on the first high-k dielectric layer HK1. The first dipole layer DPL1 may be formed having an extremely small thickness less than of about 1 nm on the first high-k dielectric layer HK1. The formation of the first dipole layer DPL1 may include allowing the first dipole layer DPL1 to undergo a heat treatment process to diffuse a first dipole element in the first dipole layer DPL1 into the first high-k dielectric layer HK1.

The second high-k dielectric layer HK2, the second dipole layer DPL2, and the third high-k dielectric layer HK3 may be sequentially formed on the first dipole layer DPL1. The formation of each of the second and third high-k dielectric layers HK2 and HK3 may be substantially the same as the formation of the first high-k dielectric layer HK1. The formation of the second dipole layer DPL2 may be substantially the same as the formation of the first dipole layer DPL1.

According to an example embodiment, a surface treatment process may further be performed after the formation of each of the first, second, and third high-k dielectric layers HK1, HK2, and HK3. The surface treatment process may include a heat treatment process that uses nitrogen (N), oxygen (O), fluorine (F), or a combination thereof. There may thus be a reduction in oxygen defect present on surfaces of the first, second, and third high-k dielectric layers HK1, HK2, and HK3. For example, at least one of the first, second, and third high-k dielectric layers HK1, HK2, and HK3 may include nitrogen (N), oxygen (O), fluorine (F), or a combination thereof.

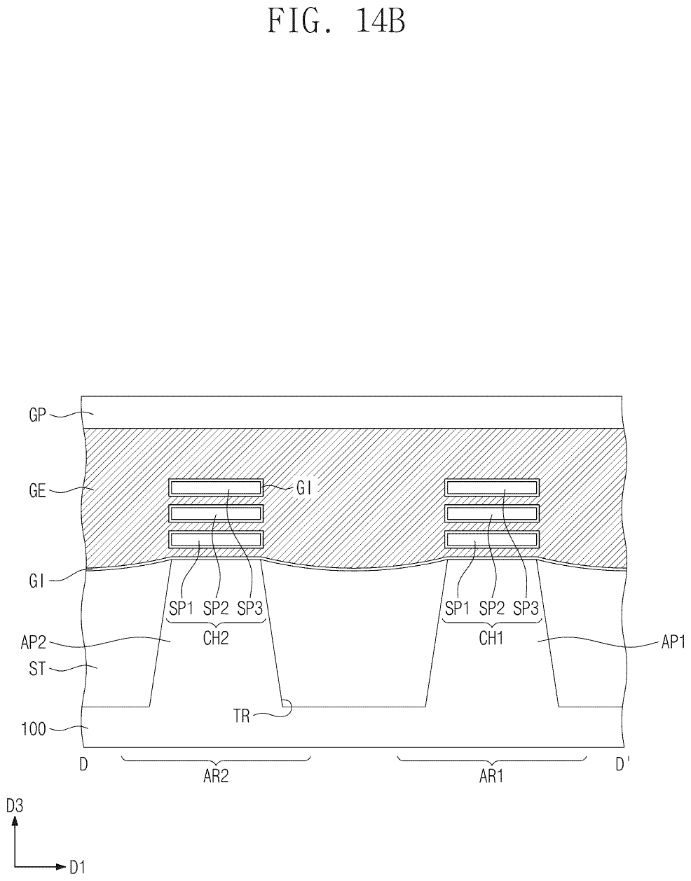

Referring to FIGS. 14A and 14B, a gate electrode GE may be formed on the gate dielectric layer GI. The formation of the gate electrode GE may include forming a metal layer that fills the first, second, and third inner regions IRG1, IRG2, and IRG3 and the outer region ORG, and recessing the metal layer. The metal layer may be recessed until the metal layer becomes lowered below the top surface of the first interlayer dielectric layer 110. Afterwards, a gate capping pattern GP may be formed on the gate electrode GE.

Referring back to FIGS. 5A to 5D, a second interlayer dielectric layer 120 may be formed on the first interlayer dielectric layer 110. The second interlayer dielectric layer 120 may include a silicon oxide layer. Active contacts AC may be formed to penetrate the second and first interlayer dielectric layers 120 and 110 to come into electrical connection with the first and second source/drain patterns SD1 and SD2. A gate contact GC may be formed to penetrate the second interlayer dielectric layer 120 and the gate capping pattern GP to come into electrical connection with the gate electrode GE.

The formation of the active contacts AC and the gate contact GC may include forming a barrier pattern and forming a conductive pattern on the barrier pattern. The barrier pattern may be formed having a uniform thickness, and may include a metal layer and a metal nitride layer. The conductive pattern may include a low-resistance metal.

A third interlayer dielectric layer 130 may be formed on the active contacts AC and the gate contact GC. A first metal layer M1 may be formed in the third interlayer dielectric layer 130. A fourth interlayer dielectric layer 140 may be formed on the third interlayer dielectric layer 130. A second metal layer M2 may be formed in the fourth interlayer dielectric layer 140.

A gate dielectric layer of a semiconductor device according to some example embodiments of the present inventive concepts may include a plurality of high-k dielectric layers. An outermost one of the plurality of high-k dielectric layers may cause the gate dielectric layer to have a thickness sufficient enough to allow a flow of a gate current on lateral surfaces of semiconductor patterns. Thus, the gate current may flow adjacent to the lateral surfaces of semiconductor patterns. Accordingly, the semiconductor device may improve in electrical characteristics.

In addition, transistors of a semiconductor device according to some example embodiments of the present inventive concepts may have different gate dielectric layers from each other. The gate dielectric layers may include different dipole elements from each other, or may include no dipole elements. Thus, the transistors in one semiconductor device may have various threshold voltages. Accordingly, the semiconductor device may improve in electrical characteristics.

Although the present inventive concepts have been described in connection with the example embodiments illustrated in the accompanying drawings, it will be understood to those skilled in the art that various changes and modifications may be made without departing from the technical spirit and scope of the claims. It therefore will be understood that the example embodiments described above are just illustrative but not limitative in all aspects.

What is claimed is:

1. A semiconductor device, comprising:
an active pattern on an active region of a substrate;
a channel pattern on the active pattern, the channel pattern including first, second, and third semiconductor patterns that are stacked to be spaced apart from each other;
a gate electrode on the channel pattern; and
a gate dielectric layer between the channel pattern and the gate electrode,
wherein the gate dielectric layer includes
an interface layer, and
first, second, and third high-k dielectric layers that are sequentially stacked on the interface layer,
wherein the first high-k dielectric layer includes a first dipole element, and
wherein the second high-k dielectric layer includes a second dipole element.

2. The semiconductor device of claim 1, wherein the gate dielectric layer further includes:
a first dipole layer between the first high-k dielectric layer and the second high-k dielectric layer; and
a second dipole layer between the second high-k dielectric layer and the third high-k dielectric layer.

3. The semiconductor device of claim 2, wherein
the first dipole layer includes the first dipole element, and
the second dipole layer includes the second dipole element.

4. The semiconductor device of claim 1, wherein a thickness of the first high-k dielectric layer on top surfaces of the first, second, and third semiconductor patterns is greater than a thickness of the first high-k dielectric layer on lateral surfaces of the first, second, and third semiconductor patterns.

5. The semiconductor device of claim 1, wherein at least one of the first, second, and third high-k dielectric layers includes nitrogen (N) and fluorine (F).

6. The semiconductor device of claim 1, wherein
one of the first dipole element and the second dipole element includes aluminum (Al), and
another of the first dipole element and the second dipole element includes lanthanum (La).

7. The semiconductor device of claim 1, wherein the first, second, and third high-k dielectric layers include different high-k dielectric materials from each other.

8. A semiconductor device, comprising:
a substrate including a first active region and a second active region that are adjacent to each other;
a first active pattern on the first active region and a second active pattern on the second active region;
a first channel pattern on the first active pattern and a second channel pattern on the second active pattern;
a first gate electrode on the first channel pattern and a second gate electrode on the second channel pattern;
a first gate dielectric layer between the first channel pattern and the first gate electrode; and
a second gate dielectric layer between the second channel pattern and the second gate electrode,
wherein each of the first and second gate dielectric layers includes a first high-k dielectric layer and a second high-k dielectric layer,
wherein the first high-k dielectric layer of the first gate dielectric layer includes a first dipole element, and
wherein the first high-k dielectric layer of the second gate dielectric layer includes a second dipole element.

9. The semiconductor device of claim 8, wherein each of the first and second channel patterns includes first, second, and third semiconductor patterns that are stacked to be spaced apart from each other.

10. The semiconductor device of claim 8, wherein
the first gate electrode includes a first metal pattern and a fill metal pattern on the first channel pattern,
the second gate electrode includes a capping pattern, a second metal pattern, and the fill metal pattern on the second channel pattern, and
the first metal pattern and the second metal pattern have different work functions from each other.

11. The semiconductor device of claim 8, wherein the first dipole element and the second dipole element are different from each other.

12. The semiconductor device of claim 8, wherein
the first dipole element increases an effective work function of the first gate electrode, and
the second dipole element decreases an effective work function of the second gate electrode.

13. The semiconductor device of claim 8, wherein the first high-k dielectric layer and the second high-k dielectric layer include a same high-k dielectric material.

14. The semiconductor device of claim 8, wherein
the first gate dielectric layer includes a first dipole layer between the first high-k dielectric layer and the second high-k dielectric layer, and
the second gate dielectric layer includes a second dipole layer between the first high-k dielectric layer and the second high-k dielectric layer.

15. The semiconductor device of claim 14, wherein each of the first and second dipole layers is provided in plural.

16. A semiconductor device, comprising:
a substrate including a first region and a second region that are spaced apart from each other;
a logic cell on the first region and including a logic transistor; and
a memory cell on the second region and including a memory transistor,
wherein the logic transistor includes
a first channel pattern,
a first gate electrode on the first channel pattern, and
a first gate dielectric layer between the first channel pattern and the first gate electrode,
wherein the memory transistor includes,
a second channel pattern,
a second gate electrode on the second channel pattern, and
a second gate dielectric layer between the second channel pattern and the second gate electrode,
wherein each of the first and second gate dielectric layers includes a first high-k dielectric layer and a second high-k dielectric layer, and
wherein the first gate dielectric layer further includes a first dipole layer between the first high-k dielectric layer and the second high-k dielectric layer.

17. The semiconductor device of claim 16, wherein
the first dipole layer includes a first dipole element that adjusts an effective work function of the first gate electrode, and
the first high-k dielectric layer of the first gate dielectric layer includes the first dipole element.

18. The semiconductor device of claim 17, wherein the second gate dielectric layer further includes a second dipole layer between the first high-k dielectric layer and the second high-k dielectric layer,
wherein the second dipole layer of the second gate dielectric layer includes a second dipole element different from the first dipole element, and
wherein the first high-k dielectric layer of the second gate dielectric layer includes the second dipole element.

19. The semiconductor device of claim 16, wherein
each of the first and second channel patterns includes first, second, and third semiconductor patterns that are stacked to be spaced apart from each other, and
each of the first and second gate dielectric layers further includes a third high-k dielectric layer on the second high-k dielectric layer.

20. The semiconductor device of claim 16, wherein
the memory cell is a static random access memory (SRAM) cell, and
the memory transistor is one of a pull-down transistor or a pull-up transistor.
